(19) United States
(12) Patent Application Publication
(10) Pub. No.: US 2026/0231541 A1
(43) Pub. Date: Aug. 6, 2026

(54) IMAGING DEVICE AND CAMERA SYSTEM

(71) Applicant: Panasonic Intellectual Property Management Co., Ltd., Osaka (JP)

(72) Inventors: HIROAKI IIJIMA, Nara (JP); SOGO OTA, Osaka (JP)

(21) Appl. No.: 19/576,116

(22) Filed: Mar. 24, 2026

Related U.S. Application Data
(63) Continuation of application No. PCT/JP2024/032187, filed on Sep. 9, 2024.

(30) Foreign Application Priority Data
Oct. 26, 2023 (JP) 2023-184009

(51) Int. Cl. H10F 39/00; H04N 23/56; H04N 25/131; H04N 25/77; H04N 25/79

(52) U.S. Cl. CPC H10F 39/8023; H04N 23/56; H04N 25/131; H04N 25/77; H04N 25/79; H10F 39/8053

(57) ABSTRACT

An imaging device includes at least one first pixel, at least one second pixel that is adjacent to the at least one first pixel in a plan view, and a photoelectric conversion layer that lies astride the at least one first pixel and the at least one second pixel, that is shared by the at least one first pixel and the at least one second pixel, and that absorbs visible light. The at least one first pixel includes a first pixel electrode that collects first signal charge generated by the photoelectric conversion layer and that has a light blocking effect on the visible light and near-infrared light. The at least one second pixel includes a photodiode that generates second signal charge by absorbing the near-infrared light transmitted through the photoelectric conversion layer.

### BACKGROUND

### 1. Technical Field

The present disclosure relates to an imaging device and a camera system.

### 2. Description of the Related Art

Conventionally, there has been proposed an imaging device including a photodiode provided in a substrate and a photoelectric conversion layer stacked over the substrate. In such an imaging device, either the photodiode or the photoelectric conversion layer converts visible light into electric charge, and the other converts near-infrared light into electric charge, whereby both the visible light and the near-infrared light can be imaged (see, for example, Japanese Unexamined Patent Application Publication No. 2017-208496, Japanese Unexamined Patent Application Publication No. 2008-218787, and Japanese Unexamined Patent Application Publication No. 2017-11273).

### SUMMARY

In one general aspect, the techniques disclosed here feature an imaging device including at least one first pixel, at least one second pixel that is adjacent to the at least one first pixel in a plan view, and a photoelectric conversion layer that lies astride the at least one first pixel and the at least one second pixel, that is shared by the at least one first pixel and the at least one second pixel, and that absorbs visible light. The at least one first pixel includes a first pixel electrode that collects first signal charge generated by the photoelectric conversion layer and that has a light blocking effect on the visible light and near-infrared light. The at least one second pixel includes a photodiode that generates second signal charge by absorbing the near-infrared light transmitted through the photoelectric conversion layer.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a block diagram showing an example of a configuration of an imaging device according to Embodiment 1;

FIG. 2 is a schematic view showing an exemplary circuit configuration of visible light pixels according to Embodiment 1 and circuits that are connected to the visible light pixels;

FIG. 3 is a schematic view showing an exemplary circuit configuration of near-infrared light pixels according to Embodiment 1 and circuits that are connected to the near-infrared light pixels;

FIG. 4 is a plan view showing an example of a planar layout of visible light pixels and near-infrared light pixels according to Embodiment 1;

FIG. 5 is a cross-sectional view showing an example of a cross-sectional structure of a visible light pixel and a near-infrared light pixel according to Embodiment 1;

FIG. 6 is a diagram showing an example of the absorption spectrum of a photoelectric conversion layer according to Embodiment 1;

FIG. 7 is a diagram showing examples of the transmission spectra of color filters according to Embodiment 1;

FIG. 8 is a cross-sectional view showing another example of a cross-sectional structure of a visible light pixel and a near-infrared light pixel according to Embodiment 1;

FIG. 9 is a cross-sectional view showing still another example of a cross-sectional structure of a visible light pixel and a near-infrared light pixel according to Embodiment 1;

FIG. 10 is a plan view showing another example of a planar layout of visible light pixels and near-infrared light pixels according to Embodiment 1;

FIG. 11 is a plan view showing still another example of a planar layout of visible light pixels and near-infrared light pixels according to Embodiment 1;

FIG. 12 is a plan view showing an example of a planar layout of visible light pixels and a near-infrared light pixel according to Modification 1 of Embodiment 1;

FIG. 13 is a cross-sectional view showing an example of a cross-sectional structure of a visible light pixel and a near-infrared light pixel according to Modification 1 of Embodiment 1;

FIG. 14 is a plan view showing another example of a planar layout of visible light pixels and a near-infrared light pixel according to Modification 1 of Embodiment 1;

FIG. 15 is a plan view showing an example of a planar layout of visible light pixels and near-infrared light pixels according to Modification 2 of Embodiment 1;

FIG. 16 is a cross-sectional view showing an example of a cross-sectional structure of a visible light pixel and a near-infrared light pixel according to Modification 2 of Embodiment 1;

FIG. 17 is a plan view showing another example of a planar layout of visible light pixels and a near-infrared light pixel according to Modification 2 of Embodiment 1;

FIG. 18 is a block diagram showing an example of a configuration of a camera system according to Embodiment 2; and

FIG. 19 is a diagram showing an example of the transmission spectrum of a double band-pass filter and an example of the emission spectrum of a near-infrared light source according to Embodiment 2.

### DETAILED DESCRIPTIONS

### Underlying Knowledge Forming Basis of an Aspect of the Present Disclosure

Prior to a specific description of embodiments of the present disclosure, the underlying knowledge forming the basis of an aspect of the present disclosure is described. The inventors found that a conventional imaging device that includes a photoelectric conversion layer and a photodiode and that images visible light and near-infrared light has the following problems.

Japanese Unexamined Patent Application Publication No. 2017-208496 discloses an imaging device in which a photoelectric conversion layer converts visible light into electric charge and a photodiode converts near-infrared light into electric charge. In the imaging device disclosed in Japanese Unexamined Patent Application Publication No. 2017-208496, a transparent electrode that transmits near-infrared light is used as a pixel electrode that traps signal charge that the photoelectric conversion layer generated by photoelectric conversion. However, in the imaging device thus configured, in which the transparent electrode is used as the pixel electrode, near-infrared light transmitted through the pixel electrode negatively affects a detection circuit component, such as a transistor, formed on a substrate, undesirably ending up with an increase in noise. Further, visible light not absorbed by the photoelectric conversion layer is transmitted through the pixel electrode, causing a further increase in noise and a decrease in the sensitivity of the photoelectric conversion layer to visible light.

Further, Japanese Unexamined Patent Application Publication No. 2008-218787 discloses an imaging device in which a photoelectric conversion layer converts near-infrared light into electric charge and a photodiode converts visible light into electric charge. In the imaging device disclosed in Japanese Unexamined Patent Application Publication No. 2008-218787, a pixel electrode that traps signal charge that the photoelectric conversion layer generated by photoelectric conversion is provided with an opening, and visible light transmitted through the photoelectric conversion layer and traveling through the opening is converted by the photodiode into electric charge. However, in the imaging device thus configured, in which the photoelectric conversion layer used has sensitivity to near-infrared light, the photoelectric conversion layer undesirably also has sensitivity to visible light, as it is difficult to achieve a photoelectric conversion layer having sensitivity solely to near-infrared light. Therefore, part of visible light arriving at the photodiode is absorbed by the photoelectric conversion layer, so that there is a decrease in the sensitivity of imaging of visible light. Further, since signal charge generated by photoelectric conversion in the photoelectric conversion layer contains a component generated by visible light as well as a component generated by near-infrared light, there is a decrease in wavelength separability of visible light and near-infrared light. In such a case, using for authentication or other purposes data obtained by imaging near-infrared light may cause a decrease in authentication accuracy.

Further, Japanese Unexamined Patent Application Publication No. 2017-11273 discloses an imaging device in which a photoelectric conversion layer converts near-infrared light into electric charge and a photodiode converts visible light into electric charge. In the imaging device disclosed in Japanese Unexamined Patent Application Publication No. 2017-11273, a pixel electrode that traps signal charge that the photoelectric conversion layer generated by photoelectric conversion and the photodiode are placed in positions different from each other in a plan view, and visible light transmitted through the photoelectric conversion layer is converted by the photodiode into electric charge. As is the case with the imaging device disclosed in Japanese Unexamined Patent Application Publication No. 2008-218787, the imaging device thus configured suffers from a decrease in the sensitivity of imaging of visible light and a decrease in wavelength separability of visible light and near-infrared light. As in the case with the imaging device disclosed in Japanese Unexamined Patent Application Publication No. 2017-208496, the imaging device disclosed in Japanese Unexamined Patent Application Publication No. 2017-11273, in which the transparent electrode or a semitransparent electrode is used as the pixel electrode, suffers from an increase in noise and a decrease in the sensitivity of the photoelectric conversion layer to visible light due to transmission of visible light through the pixel electrode.

One non-limiting and exemplary embodiment provides an imaging device and a camera system that can image both visible light and near-infrared light and that are capable of improving sensitivity and reducing noise.

### Brief Overview of the Present Disclosure

As a brief overview of the present disclosure, the following shows examples of an imaging device and a camera system according to the present disclosure.

An imaging device according to a first aspect of the present disclosure includes at least one first pixel, at least one second pixel that is adjacent to the at least one first pixel in a plan view, and a photoelectric conversion layer that lies astride the at least one first pixel and the at least one second pixel, that is shared by the at least one first pixel and the at least one second pixel, and that absorbs visible light. The at least one first pixel includes a first pixel electrode that collects first signal charge generated by the photoelectric conversion layer and that has a light blocking effect on the visible light and near-infrared light. The at least one second pixel includes a photodiode that generates second signal charge by absorbing the near-infrared light transmitted through the photoelectric conversion layer.

This makes it possible to image the visible light with the first pixel and image the near-infrared light with the second pixel. In so doing, since the photodiode of the second pixel absorbs the near-infrared light transmitted through the photoelectric conversion layer, the absorption of light by the photodiode does not affect the absorption of the visible light by the photoelectric conversion layer, so that the sensitivity of the first pixel can be improved. Further, since the photoelectric conversion layer, which absorbs the visible light, can be easily designed to have the characteristics of hardly absorbing the near-infrared light and it becomes easier for the photodiode to receive the near-infrared light, the sensitivity of the second pixel can be improved. Further, since a light blocking electrode is used as the pixel electrode of the first pixel, light is blocked by the pixel electrode and the effect of the light on a pixel circuit can be reduced, so that noise can be reduced. Therefore, the imaging device can image both the visible light and the near-infrared light and is capable of sensitivity improvement and noise reduction. Further, since a visible light component of light arriving at the photodiode is absorbed by the photoelectric conversion layer, there is improvement in wavelength separability of the near-infrared light in the second pixel.

Further, for example, an imaging device according to a second aspect of the present disclosure may be directed to the imaging device according to the first aspect, in which the at least one second pixel may include a color filter that is located above a surface of the photoelectric conversion layer on which light is incident, that transmits a component of a wavelength band of at least part of the near-infrared light, and that blocks a component of a wavelength band of at least part of the visible light.

This makes it possible, with the color filter, to further reduce the visible light incident on the photodiode, thus bringing about further improvement in wavelength separability of the near-infrared light in the second pixel.

Further, for example, an imaging device according to a third aspect of the present disclosure may be directed to the imaging device according to the second aspect, in which an aggregate average transmittance of the color filter of the at least one second pixel and the photoelectric conversion layer with respect to all wavelength bands of the visible light may be lower than or equal to 6%.

This makes it possible to attain lower transmittance in all wavelength bands of the visible light with the color filter and the photoelectric conversion layer, thus bringing about further improvement in wavelength separability of the near-infrared light in the second pixel.

Further, for example, an imaging device according to a fourth aspect of the present disclosure may be directed to the imaging device according to the second or third aspect, in which the color filter of the at least one second pixel may be a black color filter having absorption in all wavelength bands of the visible light.

This causes all wavelength bands of the visible light to be absorbed by the color filter, thus bringing about further improvement in wavelength separability of the near-infrared light in the second pixel.

Further, for example, an imaging device according to a fifth aspect of the present disclosure may be directed to the imaging device according to the second or third aspect, in which the color filter of the at least one second pixel may be a blue color filter that transmits blue light or a green color filter that transmits green light.

The blue or green color filter absorbs red light. Therefore, red light, which is often hardly absorbed by the photoelectric conversion layer, which absorbs the visible light, is absorbed by the color filter, and light transmitted through the color filter and the photoelectric conversion layer turns into light from which all wavelength bands of the visible light have been absorbed. This brings about further improvement in wavelength separability of the near-infrared light in the second pixel.

Further, for example, an imaging device according to a sixth aspect of the present disclosure may be directed to the imaging device according to any one of the first to fifth aspects, and may further comprise a plurality of pixel groups each including the at least one first pixel and the at least one second pixel, in which the plurality of pixel groups may be two-dimensionally arranged in the plan view.

This brings about improvement in viewability of an image obtained by imaging and ease with which a process such as authentication is performed using data obtained by imaging.

Further, for example, an imaging device according to a seventh aspect of the present disclosure may be directed to the imaging device according to the sixth aspect, in which each of the plurality of pixel groups may further include a third pixel and a fourth pixel, the photoelectric conversion layer may lie astride the at least one first pixel, the at least one second pixel, the third pixel, and the fourth pixel and may be shared by the at least one first pixel, the at least one second pixel, the third pixel, and the fourth pixel, the third pixel may include a second pixel electrode that collects third signal charge generated by the photoelectric conversion layer and that has a light blocking effect on the visible light and the near-infrared light, the fourth pixel may include a third pixel electrode that collects fourth signal charge generated by the photoelectric conversion layer and that has a light blocking effect on the visible light and the near-infrared light, the at least one first pixel, the third pixel, and the fourth pixel may be each located above a surface of the photoelectric conversion layer on which light is incident and may each include a color filter that blocks a component of a wavelength band of part of the visible light, and the color filter of the at least one first pixel, the color filter of the third pixel, and the color filter of the fourth pixel may block light of wavelength bands of the visible light, the wavelength bands being different from one another.

This makes an arrangement of color filters such as a Bayer arrangement possible, bringing about improvement in ease with which a process such as authentication is performed using data obtained by imaging.

Further, for example, an imaging device according to an eighth aspect of the present disclosure may be directed to the imaging device according to any one of the first to seventh aspects, and may further include a pixel array including a plurality of pixels, in which the at least one first pixel may include a plurality of first pixels, the at least one second pixel may include a plurality of second pixels, the plurality of pixels may include the plurality of first pixels and the plurality of second pixels, and a proportion of the plurality of second pixels in all pixels included in the pixel array may be smaller than 25%.

This allows even an imaging device that can image the near-infrared light with the second pixels to reduce deterioration of resolution in imaging of the visible light.

Further, for example, an imaging device according to a ninth aspect of the present disclosure may be directed to the imaging device according to any one of the first to eighth aspects, in which the photoelectric conversion layer may have sensitivity in a band of wavelengths of 400 nm to 600 nm, and the sensitivity of the photoelectric conversion layer may gradually decrease with increasing wavelength longer than 600 nm.

Human vision peaks at a wavelength of approximately 555 nm and decreases with increasing wavelength longer than 600 nm. Therefore, by decreasing the sensitivity of the photoelectric conversion layer with increasing wavelength longer than 600 nm as is the case with human vision, an image taken of the visible light can be made a naturally colored image that is close to actual appearance.

Further, for example, an imaging device according to a tenth aspect of the present disclosure may be directed to the imaging device according to any one of the first to ninth aspects, and may further include a metal grid or an air gap located between the first pixel electrode and the photodiode in the plan view and above a surface of the photoelectric conversion layer on which light is incident.

This makes it possible, with the light blocking structure located between the pixel electrode and the photodiode in the plan view, to inhibit light from being incident on the pixel circuit and reduce noise.

Further, for example, an imaging device according to an eleventh aspect of the present disclosure may be directed to the imaging device according to any one of the first to tenth aspects, may further include a substrate that includes the photodiode, and may further include a metal layer located between the photoelectric conversion layer and the substrate in a stack direction and between the first pixel electrode and the photodiode in the plan view, in which the photoelectric conversion layer may be stacked over the substrate.

This makes it possible, with the metal layer located between the pixel electrode and the photodiode in the plan view, to inhibit light from being incident on the pixel circuit and reduce noise.

Further, for example, an imaging device according to a twelfth aspect of the present disclosure may be directed to the imaging device according to any one of the first to eleventh aspects, and may further include a shield electrode that is located between the first pixel electrode and the photodiode in the plan view and that has a light blocking effect on the visible light and the near-infrared light.

This makes it possible, with the shield electrode located between the pixel electrode and the photodiode in the plan view, to inhibit light from being incident on the pixel circuit and reduce noise.

Further, for example, an imaging device according to a thirteenth aspect of the present disclosure may be directed to the imaging device according to any one of the first to twelfth aspects, may further include a substrate that includes the photodiode, and may further include a via that is connected to the shield electrode, that is located between the shield electrode and the substrate and between the first pixel electrode and the photodiode in the plan view, and that has a light blocking effect on the visible light and the near-infrared light, in which the photoelectric conversion layer may be stacked over the substrate.

This makes it possible, with the via, to inhibit light being incident obliquely on the photoelectric conversion layer in the second pixel from being incident on the pixel circuit of the first pixel and reduce noise.

Further, for example, an imaging device according to a fourteenth aspect of the present disclosure may be directed to the imaging device according to any one of the first to thirteenth aspects, in which the at least one first pixel may further include a first microlens, the at least one second pixel may further include a second microlens, and a curvature of the second microlens may be smaller than a curvature of the first microlens.

According to this configuration, the second pixel, in which the photodiode generates the second signal charge by absorbing the near-infrared light transmitted through the photelectric conversion layer, is longer in microlens focal length than the first pixel, in which the photoelectric conversion layer generates the first signal charge by absorbing the visible light. This makes it easier for the microlenses to condense light at points corresponding to the photoelectric conversion layer of the first pixel and the photodiode of the second pixel that generate signal charge. This makes it possible to improve sensitivity in the first pixel and the second pixel.

Further, for example, an imaging device according to a fifteenth aspect of the present disclosure may be directed to the imaging device according to any one of the first to thirteenth aspects, in which the at least one first pixel may further include a first microlens, the at least one second pixel may further include a second microlens, and the first pixel electrode may be eccentrically located in one predetermined direction from a center of the first microlens in the plan view.

This makes it possible to use a detection result of the first pixel in phase difference detection.

Further, for example, a camera system according to a sixteenth aspect of the present disclosure includes the imaging device according to any one of the first to fifteenth aspects and a double band-pass filter that has transmitting regions in both a wavelength band of the visible light and a wavelength band of the near-infrared light. The visible light and the near-infrared light transmitted through the double band-pass filter are incident on the photoelectric conversion layer.

This brings about improvement in wavelength separability of the visible light and the near-infrared light in the first pixel and the second pixel.

Further, for example, a camera system according to a seventeenth aspect of the present disclosure includes the imaging device according to any one of the first to fifteenth aspects and a light source that emits the near-infrared light. The imaging device detects reflected light produced by an object reflecting the near-infrared light emitted by the light source.

This makes it possible to irradiate the object with the near-infrared light according to the sensitivity characteristics of the second pixel, thus bringing about improvement in wavelength separability of the near-infrared light in the second pixel.

The following describes embodiments of the present disclosure in concrete terms with reference to the drawings. It should be noted that the embodiments to be described below each illustrate a comprehensive and specific example. The numerical values, shapes, materials, constituent elements, placement and topology of constituent elements, steps, orders of steps, or other features that are shown in the following embodiments are just a few examples and are not intended to limit the present disclosure. Various aspects described herein can be combined with each other unless a contradiction arises. Further, those of the constituent elements in the following embodiments which are not recited in an independent claim are described as optional constituent elements. Further, in the drawings, constituent elements having substantially the same functions are given common reference signs, and a repeated description may be omitted or simplified.

Further, the various elements shown in the drawings are merely schematically shown for understanding of the present disclosure, and dimensional ratios and appearances can be different from those of actual elements. That is, the drawings are schematic views and are not necessarily strict illustrations. Accordingly, for example, the drawings are not necessarily to scale.

Further, terms used herein to show the way in which elements are interrelated, such as "parallel" or "coincide", terms used herein to show the shape of an element, such as "circular" or "rectangular", and ranges of numerical values used herein are not expressions that represent only exact meanings but expressions that are meant to also encompass substantially equivalent ranges, e.g. differences of approximately several percent.

Further, the terms "above" and "below" used herein do not refer to an upward direction (upward in a vertical direction) and a downward direction (downward in a vertical direction) in absolute space recognition, but are used as terms that are defined by a relative positional relationship on the basis of an order of stacking in a stack configuration. Specifically, the term "above" refers to an optical incidence side of an imaging device, and the term "below" refers to a side of the imaging device that faces away from the optical incidence side. The same applies to an "upper surface" and a lower surface" of each member. That is, the term "upper surface" refers to an optical incidence surface of the imaging device, and the term "lower surface" refers to a surface that faces away from the optical incidence surface. It should be noted that terms such as "above", "below", "upper surface", and "lower surface" are used solely to designate the mutual placement of members and are not intended to limit the attitude of the imaging device during use. Further, the terms "above" and "below" are applied not only in a case where two constituent elements are placed at a spacing from each other and another constituent element is present between the two constituent elements, but also in a case where two constituent elements are placed in close contact with each other and the two constituent elements touch each other. Further, the term "plan view" herein refers to a view from a direction perpendicular to a n upper surface of a semiconductor substrate (in other words, a thickness direction of the semiconductor substrate).

Further, in the description and the drawings, the X axis, the Y axis, and the Z axis represent the three axes of a three-dimensional orthogonal coordinate system. In the following embodiments, the Z-axis direction is the thickness direction of the semiconductor substrate and a stack direction in which the semiconductor substrate and a photoelectric conversion layer stacked over the semiconductor substrate are arranged. Further, the negative side of the Z axis faces "downward", and the positive side of the Z axis faces "upward".

Further, the clause "a transistor is placed on a surface of the semiconductor substrate" means that a gate and source of the transistor and a drain of the transistor are placed with the surface interposed therebetween.

Further, not only visible light but also invisible light such as ultraviolet light and near-infrared light are herein expressed as "light" for convenience.

### Embodiment 1

An imaging device according to Embodiment 1 is described.

### Overall Configuration

First, an overall configuration of an imaging device according to the present embodiment is described.

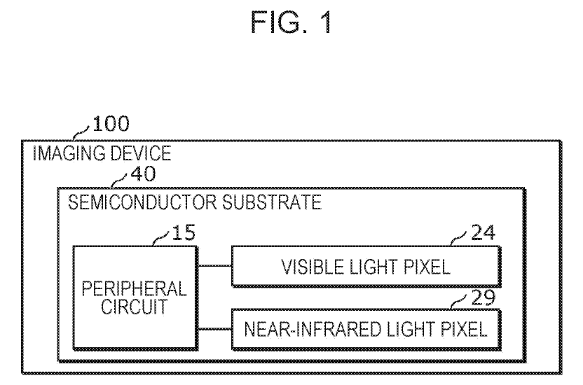

FIG. 1 is a block diagram showing an example of a configuration of an imaging device 100 according to the present embodiment.

As shown in FIG. 1, the imaging device 100 includes a semiconductor substrate 40, a peripheral circuit 15 formed on the semiconductor substrate 40, a visible light pixel 24 formed on the semiconductor substrate 40, and a near-infrared light pixel 29 formed on the semiconductor substrate 40. The semiconductor substrate 40 is an example of a substrate. The imaging device 100 is, for example, an image sensor implemented as a one-chip integrated circuit. It should be noted that components formed on the semiconductor substrate 40 include not only those formed in the semiconductor substrate 40 and over the semiconductor substrate 40 but also stacked components formed at least either above or below the semiconductor substrate 40. Further, although the visible light pixel 24 and the near-infrared light pixel 29 are each indicated by one block in FIG. 1, a plurality of the visible light pixels 24 and a plurality of the near-infrared light pixels 29 can be two-dimensionally arranged on the semiconductor substrate 40.

The visible light pixel 24 is a pixel that has sensitivity to a wavelength band of at least part of visible light and that serves to image visible light falling on the imaging device 100. The near-infrared light pixel 29 is a pixel that has sensitivity of a wavelength band of at least part of near-infrared light and that serves to image near-infrared light falling on the imaging device 100. The wavelength of near-infrared light is herein longer than or equal to 680 nm and shorter than or equal to 3000 nm. Further, the wavelength of visible light is longer than or equal to 380 nm and shorter than 680 nm. It should be noted that the near-infrared light pixel 29 may have sensitivity to at least part of a band of wavelengths of 680 nm to 1700 nm and may have sensitivity to at least part of a band of wavelengths of 700 nm to 1000 nm.

The peripheral circuit 15 is a circuit that is electrically connected to the visible light pixel 24 and the near-infrared light pixel 29 and that serves to drive the visible light pixel 24 and the near-infrared light pixel 29 and acquire signals from the visible light pixel 24 and the near-infrared light pixel 29. The peripheral circuit 15 can include a load circuit, a signal processing circuit, an output circuit, a control circuit, a power supply that supplies a predetermined voltage to the visible light pixel 24 and the near-infrared light pixel 29, or other components. The peripheral circuit 15 may cause the visible light pixel 24 and the near-infrared light pixel 29 to be driven by a global shutter method or to be driven by a rolling shutter method. It should be noted that at least part of the peripheral circuit 15 may be placed on another semiconductor substrate that is different from the semiconductor substrate 40. That is, at least part of the peripheral circuit 15 may not be formed on the semiconductor substrate 40.

### Circuit Configuration

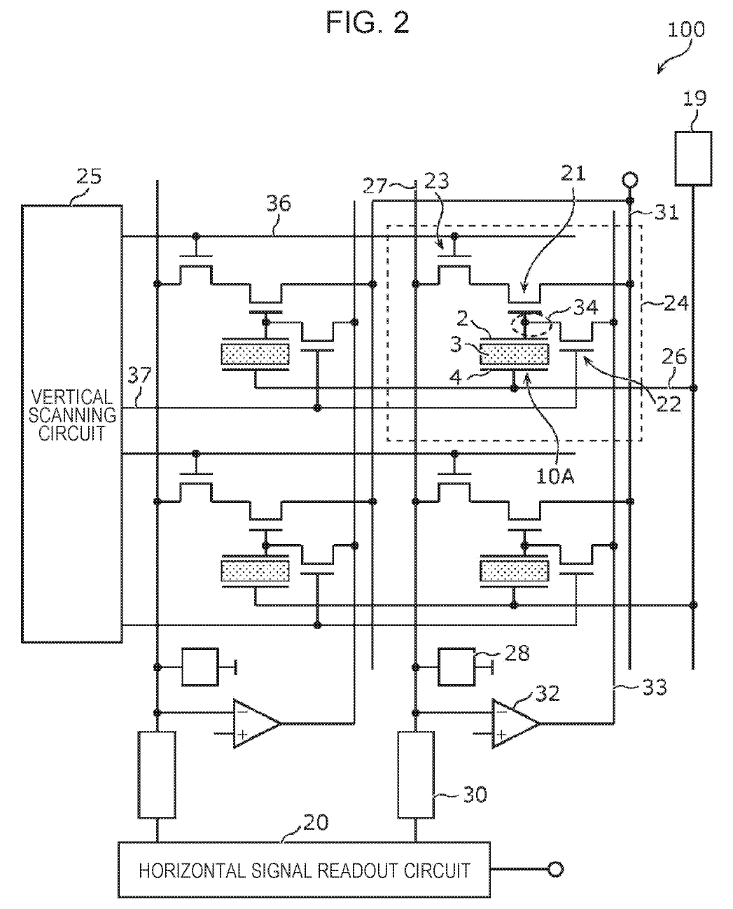

Next, a circuit configuration of visible light pixels 24, near-infrared light pixels 29, and a peripheral circuit 15 according to the present embodiment is described. First, a circuit configuration of visible light pixels 24 and circuits of the peripheral circuit 15 that are connected to the visible light pixels 24 is described. FIG. 2 is a schematic view showing an exemplary circuit configuration of visible light pixels 24 according to the present embodiment and circuits that are connected to the visible light pixels 24.

As shown in FIG. 2, the imaging device 100 includes a plurality of visible light pixels 24 and includes, as circuits of the peripheral circuit 15 that are connected to the plurality of visible light pixels 24, a voltage supply circuit 19, a vertical scanning circuit 25, a horizontal signal readout circuit 20, a plurality of column signal processing circuits 30, a plurality of load circuits 28, and a plurality of differential amplifiers 32.

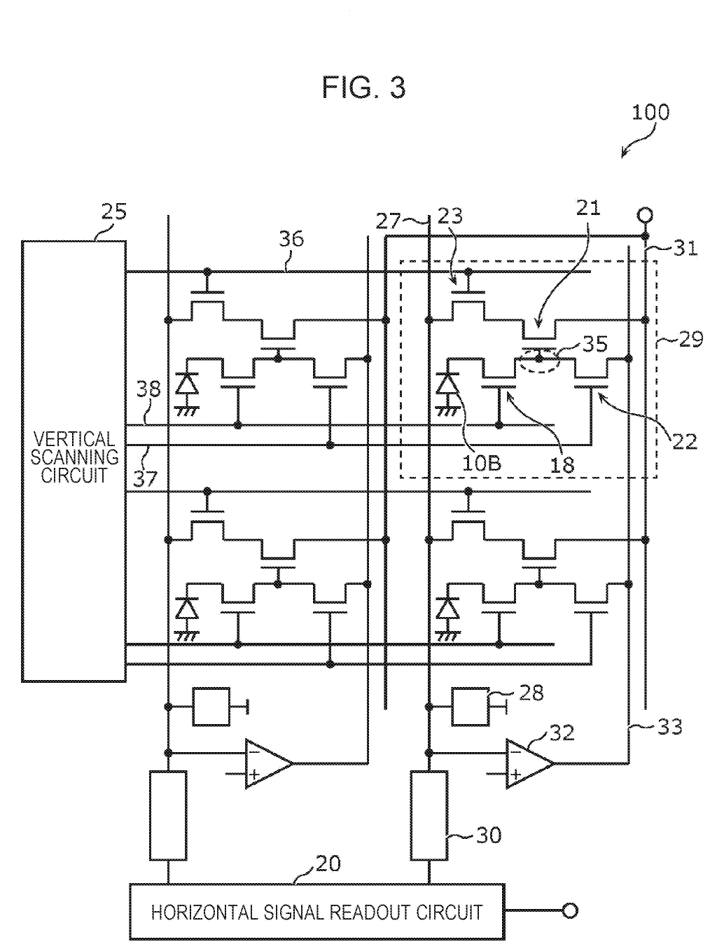

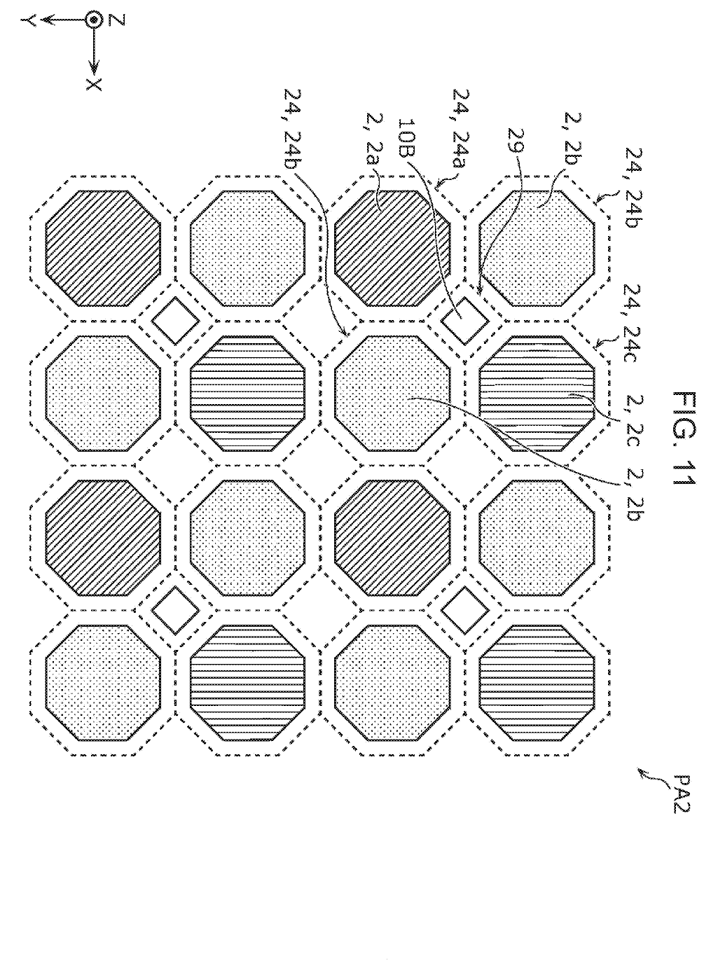

The plurality of visible light pixels 24 are two-dimensionally arranged over the semiconductor substrate 40. Specifically, the plurality of visible light pixels 24 are arranged in the row-wise direction and the column-wise direction. Although FIG. 2 shows a circuit configuration of visible light pixels 24 arranged in two rows and two columns, an actual arrangement of visible light pixels 24 can be different from that shown in FIG. 2. For example, a plurality of pixels including visible light pixels 24 and near-infrared light pixels 29 are arranged in the row-wise direction and the column-wise direction over the semiconductor substrate 40 to form a photosensitive area. That is, a near-infrared light pixel 29 can be included in rows and columns of visible light pixels 24. As in the case of the planar layout shown in FIG. 11, which will be described later, there may be rows and columns of only visible light pixels 24 arranged in one direction. The number of visible light pixels 24 is not limited to particular numbers. Further, the terms "row-wise direction" and "column-wise direction" herein refer to directions in which a row and a column extend, respectively. That is, in FIG. 2 and FIG. 3, which will be described later, the column-wise direction is a longitudinal direction on the surface of paper, and the row-wise direction is a lateral direction on the surface of paper.

Each of the visible light pixels 24 includes a photoelectric converter 10A, a charge detection circuit that detects signal charge generated by the photoelectric converter 10A, and a charge accumulation node 34 electrically connected to the photoelectric converter 10A and the charge detection circuit. The charge accumulation node 34 accumulates the signal charge generated by the photoelectric converter 10A, and the charge detection circuit of the visible light pixel 24 detects the signal charge accumulated in the charge accumulation node 34. The charge detection circuit of the visible light pixel 24 includes an amplifying transistor 21, a reset transistor 22, and an address transistor 23. The plurality of visible light pixels 24 are, for example, identical in circuit configuration to one another.

The photoelectric converter 10A includes a photoelectric conversion layer 3, a pixel electrode 2, and a counter electrode 4. The photoelectric converter 10A does not need to be wholly an element that is independent for each visible light pixel 24, and a portion of the photoelectric converter 10A may lie astride more than one visible light pixel 24. The photoelectric conversion layer 3 generates positive and negative electric charges by photoelectric conversion upon receiving light falling thereon. The positive and negative electric charges are typically a hole-electron pair. Either a hole or electron generated by the photoelectric conversion layer 3 is used as signal charge. In the photoelectric converter 10A, signal charge generated by the photoelectric conversion layer 3 subjecting light containing a visible light component to photoelectric conversion is trapped by the pixel electrode 2.

The pixel electrode 2 is connected to a gate of the amplifying transistor 21, and signal charge collected by the pixel electrode 2 is accumulated in the charge accumulation node 34, which is located between the pixel electrode 2 and the gate of the amplifying transistor 21. The signal charge is, for example, a hole. That is, the charge accumulation node 34 is electrically connected to the pixel electrode 2 and accumulates holes generated by the photoelectric conversion layer 3. Unless otherwise referred to, the following describes a case where the signal charge is a hole. Alternatively, the signal charge may be an electron.

To the counter electrode 4, a voltage for applying a predetermined bias voltage is supplied via a counter electrode signal line 26. When the imaging device 100 is in operation, the predetermined bias voltage is applied to the counter electrode signal line 26. The application of the predetermined bias voltage to the counter electrode 4 allows one of the positive and negative electric charges generated by photoelectric conversion to be selectively accumulated as signal charge in the charge accumulation node 34. Specifically, the application of such a bias voltage to the counter electrode 4 that the potential of the counter electrode 4 becomes higher than the potential of the pixel electrode 2 causes a hole to migrate as signal charge to the pixel electrode 2 to be accumulated in the charge accumulation node 34.

The voltage supply circuit 19 is electrically connected to the counter electrode 4 via the counter electrode signal line 26. The voltage supply circuit 19 gives a potential difference between the pixel electrode 2 and the counter electrode 4 by supplying the predetermined bias voltage to the counter electrode 4.

The amplifying transistor 21, the reset transistor 22, and the address transistor 23 are, for example, field-effect transistors (FETs) formed on the semiconductor substrate 40. Further, in the example shown in FIG. 2, N-channel MOSFETs (metal-oxide semiconductor FETs) are used as the amplifying transistor 21, the reset transistor 22, and the address transistor 23. It should be noted that which of the two diffusion regions of an FET corresponds to a source or a drain is determined by the polarity of the FET and whether the potential is high or low at that point in time. Therefore, which is a source or a drain can vary with the operating condition of the FET.

As shown in FIG. 2, the gate of the amplifying transistor 21 is electrically connected to the pixel electrode 2. Signal charge generated by the photoelectric converter 10A is accumulated in the charge accumulation node 34 between the pixel electrode 2 and the gate of the amplifying transistor 21. The charge accumulation node 34 is connected to the pixel electrode 2, the gate of the amplifying transistor 21, and either a source or drain of the reset transistor 22. The charge accumulation node 34 functions as at least part of a charge accumulation region in which to accumulate signal charge of the visible light pixel 24, and the potential of the charge accumulation node 34 corresponds to the amount of signal charge accumulated in the charge accumulation region. The charge accumulation node 34 includes a wire connecting the pixel electrode 2, the amplifying transistor 21, and the reset transistor 22. The signal charge accumulated in the charge accumulation node 34 is applied to the gate of the amplifying transistor 21 as a voltage corresponding to the amount of signal charge.

One of the source and drain of the amplifying transistor 21 is connected to a power supply wire 31 that supplies a predetermined power supply voltage to each visible light pixel 24 when the imaging device 100 is in operation. The predetermined power supply voltage is, for example, 3.3 V but is not limited to particular voltages. The amplifying transistor 21 outputs a signal voltage corresponding to the amount of signal charge generated by the photoelectric converter 10A. The other of the source and drain of the amplifying transistor 21 is connected to either a source or drain of the address transistor 23.

To the other of the source and drain of the address transistor 23, a vertical signal line 27 is connected. As shown in FIG. 2, such vertical signal lines 27 are provided separately for each of the columns of the plurality of visible light pixels 24, and to each of the vertical signal lines 27, a load circuit 28 and a column signal processing circuit 30 are connected. For example, the load circuit 28 forms a source-follower circuit together with the amplifying transistor 21.

To a gate of the address transistor 23, an address signal line 36 is connected. Such address signal lines 36 are provided separately for each of the rows of the plurality of visible light pixels 24. The address signal line 36 is connected to the vertical scanning circuit 25, and the vertical scanning circuit 25 applies to the address signal line 36 a row selection signal that controls the turning on and turning off of the address transistor 23. With this, a row to be read out is scanned in a vertical direction (i.e. the column-wise direction), and the row to be read out is selected. By controlling the turning on and turning off of the address transistors 23 via the address signal line 36, the vertical scanning circuit 25 can read out, to the corresponding vertical signal line 27, the output of the amplifying transistors 21 of the visible light pixels 24 thus selected.

After being outputted to the vertical signal line 27 via the address transistors 23, signal voltages from the visible light pixels 24 are inputted to the corresponding one of the plurality of column signal processing circuits 30 provided separately for each of the columns of the plurality of visible light pixels 24 in correspondence with the vertical signal lines 27.

The column signal processing circuit 30 performs noise suppression signal processing and analog-digital conversion (AD conversion) typified by correlated double sampling. The column signal processing circuit 30 is connected to the horizontal signal readout circuit 20. The horizontal signal readout circuit 20 reads out signals in sequence from the plurality of column signal processing circuits 30 to a horizontal common signal line.

To a gate of the reset transistor 22, a reset signal line 37 having a connection to the vertical scanning circuit 25 is connected. As is the case with the address signal line 36, such reset signal lines 37 are provided separately for each of the rows of the plurality of visible light pixels 24. By applying a row selection signal to the address signal line 36, the vertical scanning circuit 25 can select, on a row-by-row basis, visible light pixels 24 to be reset. Further, by applying, via the reset signal line 37 to the gates of the reset transistors 22, reset signals that control the turning on and turning off of the reset transistors 22, the vertical scanning circuit 25 can turn on the reset transistors 22 of the row thus selected. The turning on of the reset transistors 22 causes the potentials of the charge accumulation nodes 34 to be reset. In other words, the reset transistors 22 reset the potentials of the gates of the amplifying transistors 21 and the pixel electrodes 2.

In the example shown in FIG. 2, the other of the source and drain of the reset transistor 22 is connected to one of feedback lines 33 provided separately for each of the columns of the plurality of visible light pixels 24. That is, in this example, a voltage of the feedback line 33 is supplied to the charge accumulation node 34 as a reset voltage that initializes the signal charge generated by the photoelectric converter 10A. The aforementioned feedback line 33 is here connected to an output terminal of the corresponding one of the differential amplifiers 32, which are provided separately for each of the columns of the plurality of visible light pixels 24.

Attention is paid here to one of the columns of the plurality of visible light pixels 24. As shown in FIG. 2, an inverting input terminal of the differential amplifier 32 is connected to the vertical signal line 27 of the column. Further, the output terminal of the differential amplifier 32 and one or more visible light pixels 24 belonging to the column are connected to each other via the feedback line 33. When the imaging device 100 is in operation, a predetermined input voltage is supplied to the inverting input terminal of the differential amplifier 32. By selecting one of the one or more visible light pixels 24 belonging to the column and turning on the address transistor 23 and the reset transistor 22, a feedback path through which the output of the visible light pixel 24 is negatively fed back can be formed. The formation of the feedback path causes the voltage of the vertical signal line 27 to converge at the input voltage to the inverting input terminal of the differential amplifier 32. In other words, the formation of the feedback path causes the voltage of the charge accumulation node 34 to be reset to such a voltage that the voltage of the vertical signal line 27 becomes equal in magnitude to the input voltage. A usable example of the input voltage is a voltage of arbitrary magnitude falling within a range of power supply voltage and ground voltage. For example, the input voltage is a voltage falling within a range of 0 V to 3.3 V. The differential amplifier 32 is also called a "feedback amplifier".

In the configuration illustrated in FIG. 2, the formation of the feedback path causes an alternating-current component of thermal noise to be fed back to the other of the source and drain of the reset transistor 22. In the configuration illustrated in FIG. 2, the feedback path is formed until just before the turning off of the reset transistor 22, reset noise that is generated along with the turning off of the reset transistor 22 can be reduced.

Next, a circuit configuration of near-infrared light pixels 29 and circuits of the peripheral circuit 15 that are connected to the near-infrared light pixels 29 is described. FIG. 3 is a schematic view showing an exemplary circuit configuration of near-infrared light pixels 29 according to the present embodiment and circuits that are connected to the near-infrared light pixels 29. The following description of near-infrared light pixels 29 and circuits that are connected to the near-infrared light pixels 29 is given with a focus on points of difference from the description of visible light pixels 24 and circuits that are connected to the visible light pixels 24, and a description of common features is omitted or simplified.

As shown in FIG. 3, the imaging device 100 includes a plurality of near-infrared light pixels 29 and includes, as circuits of the peripheral circuit 15 that are connected to the plurality of near-infrared light pixels 29, a vertical scanning circuit 25, a horizontal signal readout circuit 20, a plurality of column signal processing circuits 30, a plurality of load circuits 28, and a plurality of differential amplifiers 32. The circuits of the peripheral circuit 15 that are connected to the plurality of near-infrared light pixels 29 have a configuration excluding the voltage supply circuit 19 from the circuits of the peripheral circuit 15 that are connected to the plurality of visible light pixels 24. At least part of the vertically scanning circuit 25, the horizontal signal readout circuit 20, the plurality of column signal processing circuits 30, the plurality of load circuits 28, and the plurality of differential amplifiers 32 may be shared by the plurality of visible light pixels 24 and the plurality of near-infrared light pixels 29. That is, at least any of the vertically scanning circuit 25, the horizontal signal readout circuit 20, a column signal processing circuit 30, a load circuit 28, and a differential amplifier 32 may be a circuit connected to both a near-infrared light pixel 29 and a visible light pixel 24. Further, the plurality of near-infrared light pixels 29 and the plurality of visible light pixels 24 may share at least part of a wire, such as a signal line, that has a connection to the peripheral circuit 15.

The plurality of near-infrared light pixels 29 are two-dimensionally arranged over the semiconductor substrate 40. Specifically, the plurality of near-infrared light pixels 29 are arranged in the row-wise direction and the column-wise direction. Although FIG. 3 shows a circuit configuration of near-infrared light pixels 29 arranged in two rows and two columns, an actual arrangement of near-infrared light pixels 29 can be different from that shown in FIG. 3. For example, as mentioned above, a plurality of pixels including visible light pixels 24 and near-infrared light pixels 29 are arranged in the row-wise direction and the column-wise direction over the semiconductor substrate 40. As in the case of the planar layout shown in FIG. 11, which will be described later, there may be rows and columns of only near-infrared light pixels 29 arranged in one direction. Further, the number of near-infrared light pixels 29 is not limited to particular numbers.

Each of the near-infrared light pixels 29 includes a photodiode 10B, a charge detection circuit that detects signal charge generated by the photodiode 10B, and a charge accumulation node 35 provided in the charge detection circuit. The charge detection circuit of the near-infrared light pixel 29 includes an amplifying transistor 21, a reset transistor 22, an address transistor 23, and a transfer transistor 18. The charge accumulation node 35 accumulates the signal charge generated by the photodiode 10B, and the charge detection circuit of the near-infrared light pixel 29 detects the signal charge accumulated in the charge accumulation node 35. The near-infrared light pixel 29 has a circuit configuration obtained by replacing the photoelectric converter 10A and charge accumulation node 34 of a visible light pixel 24 with the photodiode 10B and the charge accumulation node 35 and adding the transfer transistor 18. Further, the plurality of near-infrared light pixels 29 may be, for example, identical in circuit configuration to one another.

The photodiode 10B is a photoelectric conversion element that generates signal charge by photoelectric conversion upon receiving light falling thereon. The signal charge generated by the photodiode 10B is transferred by the transfer transistor 18 to the charge accumulation node 35.

The transfer transistor 18 is, for example, a field-effect transistor formed on the semiconductor substrate 40. Further, in the example shown in FIG. 3, an N-channel MOSFET is used as the transfer transistor 18.

As shown in FIG. 3, either a source or drain of the transfer transistor 18 is connected to the photodiode 10B. The other of the source and drain of the transfer transistor 18 is connected to the charge accumulation node 35. To a gate of the transfer transistor 18, a transfer signal line 38 is connected. Such transfer signal lines 38 are provided separately for each of the rows of the plurality of near-infrared light pixels 29. The transfer signal line 38 is connected to the vertical scanning circuit 25. By applying, via the transfer signal line 38 to the gates of the transfer transistors 18, transfer control signals that control the turning on and turning off of the transfer transistors 18, the vertical scanning circuit 25 can turn on the transfer transistors 18. The turning on of the transfer transistors 18 causes the signal charge generated in the photodiodes 10B to be transferred to the charge accumulation nodes 35.

Signal charge generated by the photodiode 10B is accumulated in the charge accumulation node 35. The charge accumulation node 35 is connected to the other of the source and drain of the transfer transistor 18, the gate of the amplifying transistor 21, and either a source or drain of the reset transistor 22. The charge accumulation node 35 functions as at least part of a charge accumulation region in which to accumulate signal charge of the near-infrared light pixel 29, and the potential of the charge accumulation node 35 corresponds to the amount of signal charge accumulated in the charge accumulation region. The signal charge accumulated in the charge accumulation node 35 is applied to the gate of the amplifying transistor 21 as a voltage corresponding to the amount of signal charge. The reading out of the output of the amplifying transistor 21 and the resetting of the potential of the charge accumulation node 35 in a near-infrared light pixel 29 are performed through actions that are similar to those described in the description of a visible light pixel 24.

### Planar Layout and Device Structure of Pixels

Next, a planar layout and device structure of visible light pixels 24 and near-infrared light pixels 29 according to the present embodiment are described.

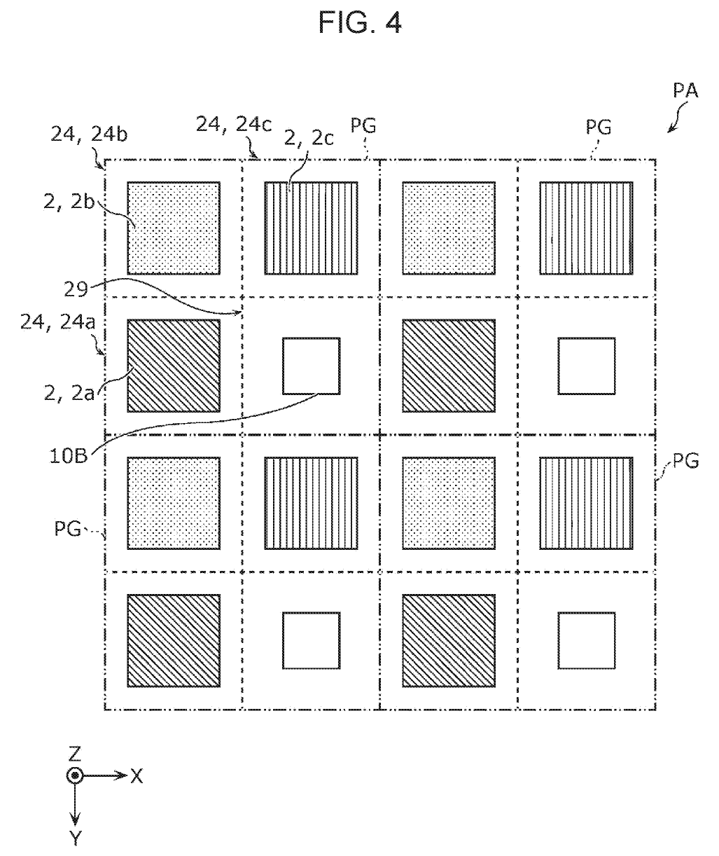

FIG. 4 is a plan view showing an example of a planar layout of visible light pixels 24 and near-infrared light pixels 29 according to the present embodiment. It should be noted that FIG. 4 omits to illustrate components other than pixel electrodes 2 and photodiodes 10B.

In FIG. 4, the boundaries between two adjacent pixels (specifically, two adjacent visible light pixels 24 or a visible light pixel 24 and a near-infrared light pixel 29 are indicated by dashed lines or chain double-dashed lines. Further, in FIG. 4, the chain double-dashed lines also indicate the boundaries between adjacent pixel groups PG. That is, the pixel groups PG are constituted by pixels located in areas surrounded by the chain double-dashed lines. In these respects, the same applies to the other planar layout diagrams to be described later. Further, in FIG. 4, at least some of the pixels of the imaging device 100 are shown, and not all of the pixels of the imaging device 100 are shown. Also in this respect, the same applies to the other planar layout diagrams to be described later.

In the example shown in FIG. 4, the plurality of visible light pixels 24 include visible light pixels 24a, 24b, and 24c including color filters (specifically, the after-mentioned color filters 60A) that block wavelength bands of visible light that are different from one another. In the present embodiment, a visible light pixel 24a is an example of at least one first pixel, a near-infrared light pixel 29 an example of at least one second pixel, a visible light pixel 24b an example of a third pixel, and a visible light pixel 24c an example of a fourth pixel. If necessary, the visible light pixels 24 may be described herein with a distinction among the visible light pixels 24a, 24b, and 24c. Further, in a case where the visible light pixels 24 are denoted with no particular distinction, the description applies to all visible light pixels 24 including the visible light pixels 24a, 24b, and 24c. Also, the pixel electrodes 2 of the visible light pixels 24 may be described with a distinction among pixel electrodes 2a of the visible light pixels 24a, pixel electrodes 2b of the visible light pixels 24b, and pixel electrodes 2c of the visible light pixels 24c. For the sake of clarity of the distinction among the visible light pixels 24a, 24b, and 24c, the pixel electrodes 2a of the visible light pixels 24a are patterned with oblique lines, the pixel electrodes 2b of the visible light pixels 24b with dots, and the pixel electrodes 2c of the visible light pixels 24c with vertical lines.

For example, one of the visible light pixels 24a, 24b, and 24c is a blue pixel including a blue color filter, another a green pixel including a green color filter, and the other a red pixel including a red color filter. In a specific example, the visible light pixels 24a are blue pixels, the visible light pixels 24b green pixels, and the visible light pixels 24c red pixels. The visible light pixels 24 may not include color filters. In this case, the visible light pixels 24 are black-and-white pixels.

FIG. 4 shows a planar layout of a pixel array PA of the imaging device 100. The pixel array PA is constituted by a plurality of pixels. The plurality of pixels constituting the pixel array PA include a plurality of visible light pixels 24a, a plurality of visible light pixels 24b, a plurality of visible light pixels 24c, and a plurality of near-infrared light pixels 29. The number of pixels that constitute the pixel array PA is not limited to particular numbers. The plurality of pixels constituting the pixel array PA are formed on the semiconductor substrate 40 and two-dimensionally arranged in a plan view. The pixel array PA forms a photosensitive area over the semiconductor substrate 40. The distance between two adjacent ones of the plurality of pixels constituting the pixel array PA can be, for example, approximately 2 μm. The distance between two adjacent pixels is also called a "pixel pitch". In the example shown in FIG. 4, two adjacent pixels are arranged in the row-wise direction or the column-wise direction. In FIG. 4, the row-wise direction is an X-axis direction, and the column-wise direction is a Y-axis direction.

An area corresponding to each pixel defined by the boundaries between two adjacent pixels illustrated is, for example, an area in which for that pixel to receive light for generating signal charge but is not necessarily an area in which all constituent elements of that pixel are included. In the example shown in FIG. 4, the shape of an area corresponding to each pixel is a square but may be another shape such as rectangle or an octagon. Since the plurality of pixels constituting the pixel array PA are regularly arranged with the pixel pitch as unit, the boundaries between two adjacent pixels are defined, for example, by the pixel pitch.

Further, the boundaries between two adjacent pixels are the positions of the sides of a square each side of which is equal in length to the pixel pitch with the centers of the pixel electrodes 2 or the photodiodes 10B coinciding with each other, for example, in a case where the pixel electrodes 2 or the photodiodes 10B are placed in the centers of the pixels. Further, the boundaries between two adjacent pixels are, for example, positions at an equal distance from the centers of two adjacent pixel electrodes 2 or positions at an equal distance from the centers of a pixel electrode 2 and a photodiode 10B that are adjacent to each other. Further, in a case where adjacent pixels include color filters of different colors, the boundaries between two adjacent pixels are, for example, the positions of the boundaries between the color filters.

Further, in the example shown in FIG. 4, the pixel array PA includes a plurality of pixel groups PG each including visible light pixels 24a, 24b, and 24c and a near-infrared light pixel 29. In the example shown in FIG. 4, each of the pixel groups PG is composed of four pixels, namely one visible light pixel 24a, one visible light pixel 24b, one visible light pixel 24c, and one near-infrared light pixel 29. The arrangements of pixels in the plurality of pixel groups PG are the same as one another and are each a minimum repeating unit of pixel arrangement in the pixel array PA. The plurality of pixel groups PG are two-dimensionally arranged in a plan view. The two-dimensional arrangement of the plurality of pixel groups PG forms, for example, a Bayer arrangement part of which is replaced by near-infrared light pixels 29. The number of pixel groups PG is not limited to particular number.

As shown in FIG. 4, in a plan view, a near-infrared light pixel 29 is adjacent to a visible light pixel 24a and a visible light pixel 24c. A visible light pixel 24 that is adjacent to a near-infrared light pixel 29 is a visible light pixel 24 including a pixel electrode 2 that is closest to the photodiode 10B of the near-infrared light pixel 29 in a plan view. Further, a visible light pixel 24b is adjacent to a visible light pixel 24a and a visible light pixel 24c and is diagonally located with respect to a near-infrared light pixel 29 in a pixel group PG.

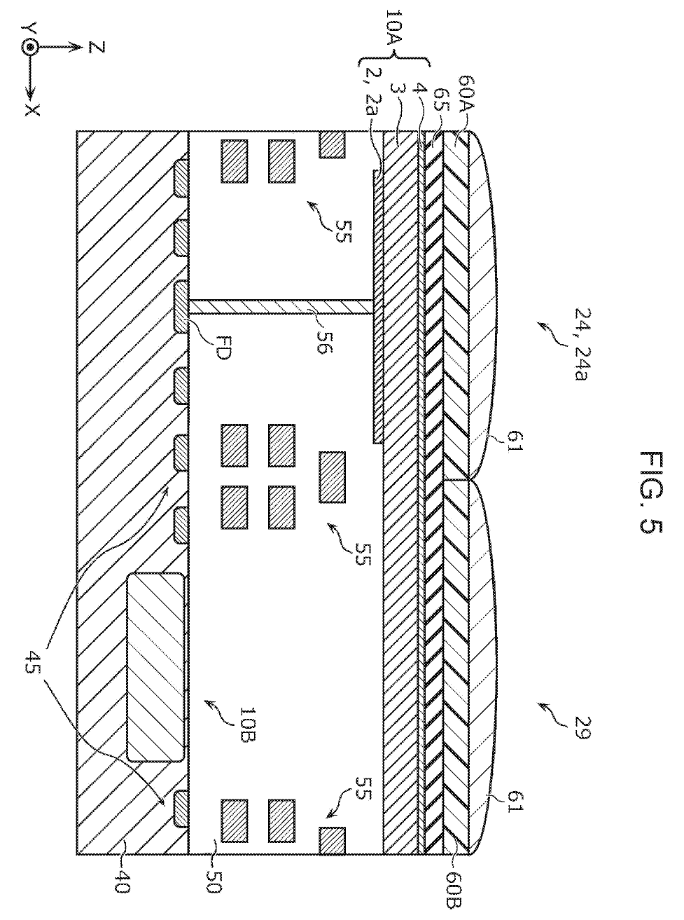

FIG. 5 is a cross-sectional view showing an example of a cross-sectional structure of a visible light pixel 24 and a near-infrared light pixel 29 according to the present embodiment. For viewability, FIG. 5 omits to illustrate hatching that indicates a cross-section of an insulating layer 50.

As shown in FIG. 5, the visible light pixel 24 and the near-infrared light pixel 29 are formed on the semiconductor substrate 40. Although FIG. 5 shows a cross-sectional structure of one visible light pixel 24a of the plurality of visible light pixels 24, the same applies to a cross-sectional structure of a visible light pixel 24b and a visible light pixel 24c. As shown in FIG. 5, the visible light pixel 24 includes a pixel electrode 2, a photoelectric conversion layer 3, a counter electrode 4, a color filter 60A, and a microlens 61. Further, the near-infrared light pixel 29 includes the photoelectric conversion layer 3, a photodiode 10B, a color filter 60B, and a microlens 61.

In the configuration shown in FIG. 5, the semiconductor substrate 40 has formed therein a transistor group 45 including a plurality of transistors. Specifically, the transistor group 45 is formed in an upper surface of the semiconductor substrate 40. The plurality of transistors included in the transistor group 45 include, for example, the amplifying transistor 21, reset transistors 22, and address transistor 23 of the aforementioned visible light pixel 24 and the amplifying transistor 21, reset transistors 22, address transistor 23, and transfer transistor 18 of the aforementioned near-infrared light pixel 29. FIG. 5 illustrates only impurity regions, formed in the semiconductor substrate 40, that function as sources or drains of the plurality of transistors included in the transistor group 45. Further, the number of impurity regions in the transistor group 45 is not limited to the example shown in FIG. 5. In these respects, the same applies to transistor groups 45 shown in subsequent cross-sectional views.

The semiconductor substrate 40 has, as one of the impurity regions in the transistor group 45, an impurity region FD in which signal charge collected by the pixel electrode 2 is accumulated. The impurity region FD functions, for example, as either the source or drain of the reset transistor 22 of the visible light pixel 24.

The semiconductor substrate 40 is not limited to a substrate made entirely of a semiconductor. The semiconductor substrate 40 may be an insulating substrate having a semiconductor layer provided on a surface thereof on which a photosensitive area is formed. An example is described here in which a P-type silicon (Si) substrate is used as the semiconductor substrate 40. In this case, the impurity regions in the transistor group 45 are N-type regions in which N-type impurities are diffused. Further, the semiconductor substrate 40 may be provided with a device isolation region for electrical separation between pixels.

Further, the semiconductor substrate 40 has a photodiode 10B formed in a position different from that of the transistor group 45 in a plan view. The photodiode 10B is, for example, an embedded photodiode formed in a silicon substrate. In this case, the photodiode 10B formed in the silicon substrate absorbs, for example, a component of near-infrared light in a band of wavelengths shorter than or equal to 1100 nm. The photodiode 10B overlaps the photoelectric conversion layer 3 in a plan view and generates signal charge by absorbing near-infrared light transmitted through the photoelectric conversion layer 3. The signal charge that the photodiode 10B generates is an example of second signal charge.

The insulating layer 50 is placed above the semiconductor substrate 40. The insulating layer 50 is, for example, formed from an insulating material such as silicon oxide. As shown in FIG. 5, the insulating layer 50 has a plurality of metal layers 55 placed therein. For example, the plurality of metal layers 55 are formed from a metal such as copper and have a light blocking effect on visible light and near-infrared light. The phrases "to have a light blocking effect" and "to block light" herein do not mean not to transmit light at all but mean substantially not to transmit light. For example, the metal layers 55 do not transmit 90% or more of visible light and near-infrared light falling thereon. The metal layers 55 may not transmit 99% or more of visible light and near-infrared light falling thereon.

For example, at least one of the plurality of metal layers 55 is a wiring layer that can include wires, such as the aforementioned vertical signal lines 27, that connect the visible light pixels 24 and the near-infrared light pixels 29 to the peripheral circuit 15 or other wires. The number of metal layers 55 that are placed in the insulating layer 50 can be arbitrarily set and is not limited to the example shown in FIG. 5.

At least one of the plurality of metal layers 55 is located between the photoelectric conversion layer 3 and the semiconductor substrate 40 in the stack direction and between the pixel electrode 2a and the photodiode 10B in a plan view. This causes the metal layer 55 to overlap, in a plan view, part of the transistor group 45 formed in the semiconductor substrate 40 and causes the part of the transistor group 45 to be covered with the metal layer 55 from above, inhibiting light from falling on the transistor group 45. This makes it possible to reduce generation of noise due to absorption of light by the transistor group 45. For example, the plurality of metal layers 55 include a metal layer 55 covering part of the transistor group 45 in the visible light pixel 24 in a plan view and a metal layer 55 covering part of the transistor group 45 in the near-infrared light pixel 29 in a plan view.

The insulating layer 50 has a plurality of vias placed therein. The plurality of vias include a via 56 connecting the pixel electrode 2 to the impurity region FD, vias (not illustrated) connecting the metal layers 55 to each other, and vias (not illustrated) connecting the metal layers 55 to the transistor group 45. The plurality of vias are each a plug formed from a metal such as aluminum, copper, or tungsten, from a metal nitride, from polysilicon rendered conductive by being doped with impurities, or from other substances. For example, the plurality of vias have a light blocking effect on visible light and near-infrared light. For example, the plurality of vias reflect visible light and near-infrared light.

As shown in FIG. 5, the visible light pixel 24 is structured such that the photoelectric conversion layer 3 is placed above the insulating layer 50 with the pixel electrode 2 sandwiched therebetween. In the example shown in FIG. 5, the visible light pixel 24 is structured such that over the semiconductor substrate 40, the pixel electrode 2, the photoelectric conversion layer 3, the counter electrode 4, a passivation layer 65, the color filter 60A, and the microlens 61 are stacked in this order from the semiconductor substrate 40 with the insulating layer 50 sandwiched between the semiconductor substrate 40 and the stack. Further, the near-infrared light pixel 29 is structured such that the photoelectric conversion layer 3 is placed above the insulting layer 50 with no pixel electrode 2 sandwiched therebetween. In the example shown in FIG. 5, the near-infrared light pixel 29 is structured such that over the semiconductor substrate 40, the photoelectric conversion layer 3, the counter electrode 4, the passivation layer 65, the color filter 60B, and the microlens 61 are stacked in this order from the semiconductor substrate 40 with the insulating layer 50 sandwiched between the semiconductor substrate 40 and the stack.

As shown in FIG. 5, the photoelectric conversion layer 3, the counter electrode 4, and the passivation layer 65 lie astride the visible light pixel 24a and the near-infrared light pixel 29 and are shared by the visible light pixel 24a and the near-infrared light pixel 29. Although not illustrated in FIG. 5, the photoelectric conversion layer 3, the counter electrode 4, and the passivation layer 65 also lie astride the visible light pixel 24b and the visible light pixel 24c and are shared by the visible light pixel 24a, the near-infrared light pixel 29, the visible light pixel 24b, and the visible light pixel 24c. Alternatively, the photoelectric conversion layer 3, the counter electrode 4, and the passivation layer 65 may lie across all of the plurality of pixels constituting the pixel array PA and be shared by the plurality of pixels.

The pixel electrode 2 is an electrode that collects signal charge generated by the photoelectric conversion layer 3. The signal charge that the pixel electrode 2a collects is an example of first signal charge. The pixel electrode 2 is electrically separated from the pixel electrodes 2 of other adjacent visible light pixels 24 by being spatially separated from the pixel electrodes 2 of the other visible light pixels 24.

The pixel electrode 2 is located below the photoelectric conversion layer 3 i.e. at a side that faces away from the optical incidence side. In the present embodiment, the optical incidence side of the imaging device 100 faces away from a side of the photoelectric conversion layer 3 that faces the semiconductor substrate 40. Therefore, the pixel electrode 2 is located between the semiconductor substrate 40 and the photoelectric conversion layer 3. In a plan view, the pixel electrode 2 overlaps part of the transistor group 45. Further, in a plan view, the pixel electrode 2 does not overlap the photodiode 10B, and the pixel electrode 2 and the photodiode 10B are separate from each other. Alternatively, in a plan view, the pixel electrode 2 may overlap part of the photodiode 10B.

The pixel electrode 2 has a light blocking effect on visible light and near-infrared light. The pixel electrode 2 may reflect visible light and near-infrared light transmitted through the photoelectric conversion layer 3. The pixel electrode 2 is formed from a metal such as aluminum, copper, or tungsten, from a metal nitride, from polysilicon rendered conductive by being doped with impurities, or from other substances. For example, a sufficient light blocking effect can be achieved by forming, as the pixel electrode 2, a TaN electrode having a thickness of 100 nm. The pixel electrode 2 is not limited to a TaN electrode as long as the pixel electrode 2 has a light blocking effect. For example, the pixel electrode 2 does not transmit 90% or more of visible light and near-infrared light falling thereon. The pixel electrode 2 may not transmit 99% or more of visible light and near-infrared light falling thereon.

The photoelectric conversion layer 3 absorbs visible light. The photoelectric conversion layer 3 is located above the pixel electrode 2 and the photodiode 10B. On the photoelectric conversion layer 3, visible light and near-infrared light transmitted through the microlens 61, the color filter 60A or 60B, the passivation layer 65, and the counter electrode 4 fall. For example, the photoelectric conversion layer 3 absorbs all wavelength bands of visible light and transmits a wavelength band of at least part of near-infrared light. The photoelectric conversion layer 3 is formed from an organic material or an inorganic material such as amorphous silicon. The photoelectric conversion layer 3 may include a plurality of layers, and the plurality of layers may include a layer composed of an organic material and a layer composed of an inorganic material.

The counter electrode 4 is located above the photoelectric conversion layer 3 and placed opposite the pixel electrode 2. The counter electrode 4 transmits visible light and near-infrared light. The counter electrode 4 is, for example, a transparent electrode formed from a transparent conducing material. The term "transparent" herein means to transmit at least part of a wavelength band of light to be detected, and it is not essential to transmit light across the whole wavelength bands of visible light and near-infrared light. For example, the counter electrode 4 transmits at least part of light of wavelengths to which the photoelectric conversion layer 3 has sensitivity and at least part light of wavelengths which the photodiode 10B has sensitivity. The transparent electrode can be made, for example, of a transparent conductive oxide (TCO) such as ITO, IZO, AZO, FTO, SnO₂, TiO₂, or ZnO₂.

Further, although not illustrated, the imaging device 100 may further include at least either an electron blocking layer or a hole blocking layer. Further, for example, the electron blocking layer and the hole blocking layer lie across all of the plurality of pixels constituting the pixel array PA and are shared by the plurality of pixels.

The electron blocking layer is provided to reduce a dark current generated by electrons being implanted from the pixel electrode 2 and inhibits electrons from being implanted from the pixel electrode 2 into the photoelectric conversion layer 3. The electron blocking layer is located below the photoelectric conversion layer 3 and, for example, is provided over the pixel electrode 2 and the insulating layer 50. Further, in the visible light pixel 24, the electron blocking layer is located between the pixel electrode 2 and the photoelectric conversion layer 3, and in the near-infrared light pixel 29, the electron blocking layer is located between the photodiode 10B and the photoelectric conversion layer 3.

The electron blocking layer is made, for example, of an organic substance such as α-NPD(N,N'-Di(1-naphthyl)-N,N'-diphenylbenzidine) and 9,9'-[1,1'-biphenyl]-4,4'-diylbis[3,6-bis(1,1-dimethyl ethyl)]-9H-carbazole, an organic metal compound, or an inorganic substance such as NiO.

The electron blocking layer transmits near-infrared light. The electron blocking layer may have a thickness, for example, greater than or equal to 2 nm and less than or equal to 50 nm.

The hole blocking layer is provided to reduce a dark current generated by holes being implanted from the counter electrode 4 and inhibits holes from being implanted from the counter electrode 4 into the photoelectric conversion layer 3. The hole blocking layer is located between the photoelectric conversion layer 3 and the counter electrode 4.

The hole blocking layer is made, for example, of an organic substance such as copper phthalocyanine, PTCDA (3,4,9,10-perylenetetracarboxylic dianhydride), an acetylacetonate complex, BCP (bathocuproine), or Alq (tris(8-quinolinolate)aluminum), an organic metal compound, or an inorganic substance such as MgAg or MgO. The hole blocking layer may be made of the acceptor organic semiconductor material as a photoelectric conversion material of the photoelectric conversion layer 3.

The hole blocking layer transmits visible light and near-infrared light. It is preferable that the hole blocking layer be high in transmittance of visible light and near-infrared light so as not to hinder absorption of light by the photoelectric conversion layer 3 and the photodiode 10B, and a material having no absorption in a wavelength band of visible light may be selected. Further, the hole blocking layer may have a reduced thickness. The thickness of the hole blocking layer may be, for example, greater than or equal to 2 nm and less than or equal to 50 nm, albeit depending on the configuration of the photoelectric conversion layer 3, the thickness of the counter electrode 4, or other factors.

Further, the electron blocking layer and the hole blocking layer may be transparent to visible light and near-infrared light.

In a case where an electron is used as signal charge, the electron blocking layer and the hole blocking layer are configured to swap positions with each other. In this case, the electron blocking layer inhibits electron from being implanted from the counter electrode 4 into the photoelectric conversion layer 3, and the hole blocking layer inhibits holes from being implanted from the pixel electrode 2 into the photoelectric conversion layer 3.

The passivation layer 65 is an insulating protective film that protects a lower layer. The passivation layer 65 transmits visible light and near-infrared light. The passivation layer 65 is formed, for example, by SiON, AlO, or other substances.

The color filters 60A and 60B are located above the photoelectric conversion layer 3. That is, the color filters 60A and 60B are located closer to the optical incidence side than is the photoelectric conversion layer 3.

The color filter 60A overlaps the pixel electrode 2 in a plan view. In the visible light pixel 24, light transmitted through the color filter 60A falls on the photoelectric conversion layer 3. The color filter 60A blocks a component of a wavelength band of part of visible light and transmits a component of a wavelength band of another part of visible light. The color filter 60A is, for example, a red, green, or blue color filter that blocks a component of a wavelength band of part of visible light. The color filter 60A may transmit near-infrared light or may block near-infrared light.

The color filter 60B overlaps the photodiode 10B in a plan view. In the near-infrared light pixel 29, light transmitted through the color filter 60B and the photoelectric conversion layer 3 falls on the photodiode 10B. The color filter 60B transmits a component of a wavelength band of at least part of near-infrared light and blocks a component of a wavelength band of at least part of visible light. The color filter 60B is , for example, a black color filter but may be a green or blue color filter. The black color filter may be a black single-layer color filter or may be a stack of multiple color filters of different colors (e.g. blue and green) that substantially functions as a black color filter. For example, the color filter 60B does not transmit 90% or more of a component of a wavelength band of at least part of visible light. The near-infrared light pixel 29 may not include the color filter 60B.

The color filters 60A and 60B are, for example, formed as on-chip color filters by patterning and made of photosensitive resin or other materials with a dye or a pigment dispersed therein. The color filters 60A and 60B are, for example, formed by a patterning process at the same timing.

The microlenses 61 are located above the photoelectric conversion layer 3. The visible light pixel 24 and the near-infrared light pixel 29 are provided separately with each of the microlenses 61. The pixel electrode 2 is located on an optical axis of the microlens 61 of the visible light pixel 24. For example, in a plan view, the center of the pixel electrode 2 and the center of the microlens 61 of the visible light pixel 24 coincide with each other. The photodiode 10B is located on an optical axis of the microlens 61 of the near-infrared light pixel 29. For example, in a plan view, the center of the photodiode 10B and the center of the microlens 61 of the near-infrared light pixel 29 coincide with each other. The microlenses 61 are formed, for example, as on-chip microlenses. The microlenses 61 are made of an ultraviolet photosensitive material or other materials.

The imaging device 100 can be manufactured by using a common semiconductor manufacturing process. In particular, in a case where a silicon substrate is used as the semiconductor substrate 40, the imaging device 100 can be manufactured by utilizing various silicon semiconductor processes.

As noted above, an imaging device 100 according to the present embodiment includes a visible light pixel 24a, a near-infrared light pixel 29 that is adjacent to the visible light pixel 24a in a plan view, and a photoelectric conversion layer 3 that lies astride the visible light pixel 24a and the near-infrared light pixel 29, that is shared by the visible light pixel 24a and the near-infrared light pixel 29, and that absorbs visible light. The visible light pixel 24a includes a pixel electrode 2a that collects first signal charge generated by the photoelectric conversion layer 3 and that has a light blocking effect on the visible light and near-infrared light. The near-infrared light pixel 29 includes a photodiode 10B that generates second signal charge by absorbing the near-infrared light transmitted through the photoelectric conversion layer 3.

This makes it possible to image the visible light with the visible light pixel 24a and image the near-infrared light with the near-infrared light pixel 29. In so doing, since the photodiode 10B of the near-infrared light pixel 29 absorbs the near-infrared light transmitted through the photoelectric conversion layer 3, the absorption of light by the photodiode 10B does not affect the absorption of the visible light by the photoelectric conversion layer 3, so that the sensitivity of the visible light pixel 24a can be improved. Further, since the photoelectric conversion layer 3, which absorbs the visible light, can be easily designed to have the characteristics of hardly absorbing the near-infrared light and it becomes easier for the photodiode 10B to receive the near-infrared light, the sensitivity of the near-infrared light pixel 29 can be improved. Further, since a light blocking electrode is used as the pixel electrode 2a of the visible light pixel 24a, light is blocked by the pixel electrode 2a and the effect of the light on a pixel circuit can be reduced, so that noise can be reduced. Therefore, the imaging device 100 can image both the visible light and the near-infrared light and is capable of sensitivity improvement and noise reduction. Further, since a visible light component of light arriving at the photodiode 10B is absorbed by the photoelectric conversion layer 3, there is improvement in wavelength separability of the near-infrared light in the near-infrared light pixel 29. That is, it become harder for the near-infrared light pixel 29 to detect a component of a wavelength band other than the near-infrared light. Therefore, for example, there is improvement in authentication accuracy in a case where data obtained by imaging the near-infrared light with the imaging device 100 is used in authentication such as face authentication.

### Characteristics of Photoelectric Conversion Layer and Color Filters

Next, the characteristics of the photoelectric conversion layer 3 and the color filters 60A and 60B are described. In the present embodiment, the visible light pixel 24 is configured such that signal charge generated by the photoelectric conversion layer 3 absorbing visible light transmitted through the color filter 60A is collected by the pixel electrode 2 and read out as a signal. Further, the near-infrared light pixel 29 is configured such that signal charge generated by the photodiode 10B absorbing near-infrared light transmitted through the color filter 60B and the photoelectric conversion layer 3 is transferred by the transfer transistor 18 and read out as a signal. The photoelectric conversion layer 3 and the color filters 60A and 60B have the characteristics of absorption and transmission of light for generating such signal charge.

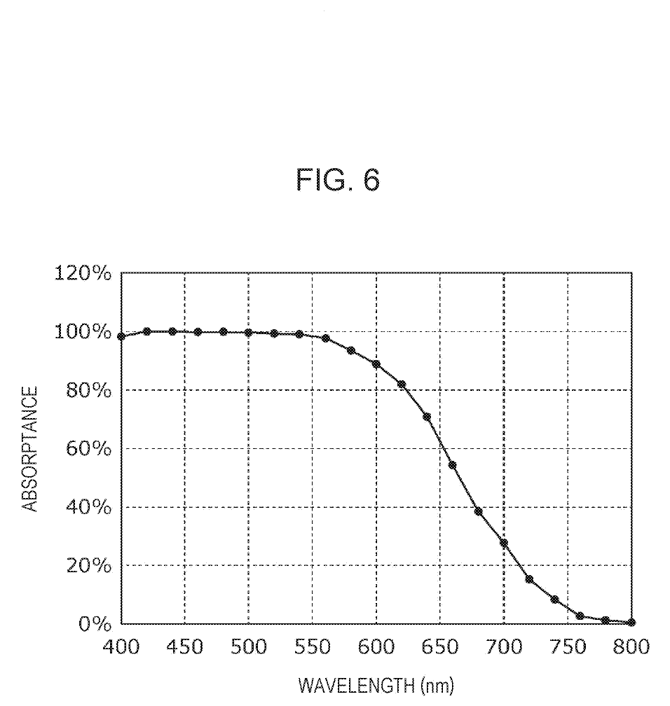

First, the optical absorption characteristics of the photoelectric conversion layer 3 are described. The photoelectric conversion layer 3 has the characteristics of absorbing visible light and transmitting near-infrared light. The photoelectric conversion layer 3 may also absorb a component of a wavelength band of part of near-infrared light. FIG. 6 is a diagram showing an example of the absorption spectrum of the photoelectric conversion layer 3. FIG. 6 shows the absorption spectrum of a photoelectric conversion layer 3 deposited so that a film thickness of 500 nm is attained by co-evaporation with a fullerene C60 to subphthalocyanine volume ratio of 4:1.

In the example shown in FIG. 6, the photoelectric conversion layer 3 has high absorptance in a band of wavelengths of 400 nm to 600 nm, and the absorptance in the band of wavelengths is higher than or equal to 80%. The photoelectric conversion layer 3 gradually decreases in absorptance with increasing wavelength longer than 600 nm. The photoelectric conversion layer 3 has an absorptance of 50% or lower in a band of wavelengths of 680 nm and longer. Further, the photoelectric conversion layer 3 has an absorption of 0 at 800 nm, and the band of wavelengths of near-infrared light includes a band of wavelengths that the photoelectric conversion layer 3 does not absorb.

Since the photoelectric conversion layer 3 performs photoelectric conversion by absorbing light, the optical absorptance of the photoelectric conversion layer 3 exhibits a positive correlation with the sensitivity of the photoelectric conversion layer 3. Therefore, the photoelectric conversion layer 3, which has the absorption spectrum shown in FIG. 6, has sensitivity in a band of wavelengths of 400 nm to 600 nm, and the sensitivity in the band of wavelengths of 400 nm to 600 nm has a higher characteristic than does the sensitivity in a band of wavelengths longer than 600 nm. Further, the photoelectric conversion layer 3, which has the absorption spectrum shown in FIG. 6, has the characteristics of gradually decreasing in sensitivity with increasing wavelength longer than 600 nm. Human vision to light peaks at a wavelength of approximately 555 nm, decreases at wavelengths longer than 555 nm, and becomes substantially zero at wavelengths of 680 nm and longer. Further, when red light is defined as light in a band of wavelengths of 600 nm to 680 nm, human vision is high at approximately 600 nm, and human vision is low at approximately 680 nm. Therefore, in the case of red pixels, a naturally colored image that is close to actual appearance can be outputted by the imaging device 100 when the sensitivity is high at 600 nm and the sensitivity decreases with increasing wavelength from 600 nm toward 680 nm. Therefore, by the photoelectric conversion layer 3 having the characteristics of gradually decreasing in sensitivity with increasing wavelength longer than 600 nm, an image taken of visible light can be made a naturally colored image that is close to actual appearance.

The absorption spectrum of the photoelectric conversion layer 3 is not limited to the example shown in FIG. 6 but can be adjusted according to photoelectric conversion materials constituting the photoelectric conversion layer 3 and the thickness of the photoelectric conversion layer 3.

For example, the photoelectric conversion layer 3 contains a donor semiconductor material and an acceptor semiconductor material as the photoelectric conversion materials. The photoelectric conversion layer 3 is made, for example, of an organic semiconductor material. Usable examples of a method for fabricating the photoelectric conversion layer 3 include a wet method such as a spin-coating method or a dry method such as a vacuum evaporation method.

The photoelectric conversion layer 3 is, for example, a bulk heterojunction structure mixed film containing a donor semiconductor material such as a donor organic semiconductor material and an acceptor semiconductor material such as an acceptor organic semiconductor material. Alternatively, the photoelectric conversion layer 3 may have a stack structure in which a layer constituted by a donor semiconductor material and a layer constituted by an acceptor semiconductor material are stacked. Further, even if the photoelectric conversion layer 3 does not have a structure in which a plurality of layers are clearly stacked, the photoelectric conversion layer 3 may be, for example, a layer having a region where the content ratio of a donor organic semiconductor material is higher than the content ratio of an acceptor semiconductor material and a region where the content ratio of an acceptor organic semiconductor material is higher than the content ratio of a donor semiconductor material.

Usable examples of donor organic semiconductor materials include metal complexes having, as ligands, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a subphthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (such as a naphthalene derivative, an anthracene derivative, a phenanthrene derivative, a tetracene derivative, a pyrene derivative, a perylene derivative, or a fluoranthene derivative), and a nitrogen-containing heterocyclic compound.

Usable examples of acceptor organic semiconductor materials include metal complexes having, as ligands, a fullerene (such as a C60 fullerene or a C70 fullerene), a fullerene derivative (such as PCBM (phenyl-C₆₁-butyric acid methyl ester) or ICBA (indene-C₆₀ bisadduct)), a condensed aromatic carbocyclic compound (such as a naphthalene derivative, an anthracene derivative, a phenanthrene derivative, a tetracene derivative, a pyrene derivative, a perylene derivative, or a fluoranthene derivative), a 5- to 7-membered heterocyclic compound containing a nitrogen atom, an oxygen atom, or a sulfur atom (such as pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole , benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, or tribenzazepine), a polyarylene compound, a fluorene compound, a cyclopentadiene compound, a silyl compound, and a nitrogen-containing heterocyclic compound.

Donor organic semiconductor materials and acceptor organic semiconductor materials are not limited to the aforementioned examples. A low-molecular organic compound and a high-molecular organic component may be used as a donor semiconductor material and an acceptor organic semiconductor material that constitute the photoelectric conversion layer 3, as long as the organic compounds can be deposited as a photoelectric conversion layer by either a dry or wet method.

Furter, the photoelectric conversion layer 3 may contain semiconductor materials other than those above as a donor semiconductor material and an acceptor semiconductor material. The photoelectric conversion layer 3 may contain, for example, a silicon semiconductor, a compound semiconductor, a quantum dot, a perovskite material, a carbon nanotube, or a mixture of two or more thereof as a semiconductor material.

At least one of the photoelectric conversion materials contained in the photoelectric conversion layer 3 has an absorption peak, for example, in a wavelength band of visible light. For example, the donor semiconductor material contained in the photoelectric conversion layer 3 has an absorption peak in a wavelength band of visible light. The absorption peak may be present in a band of wavelengths of 500 nm to 600 nm. This makes it easier to increase the sensitivity of the visible light pixel 24 to green wavelengths to which human vision is high. For example, the subphthalocyanine described in FIG. 6 above has an absorption peak at approximately 555 nm.

The thickness of the photoelectric conversion layer 3 may be, for example, greater than or equal to 50 nm, may be greater than or equal to 200 nm, or may be greater than or equal to 400 nm. Further, the thickness of the photoelectric conversion layer 3 is, for example, less than or equal to 1000 nm.

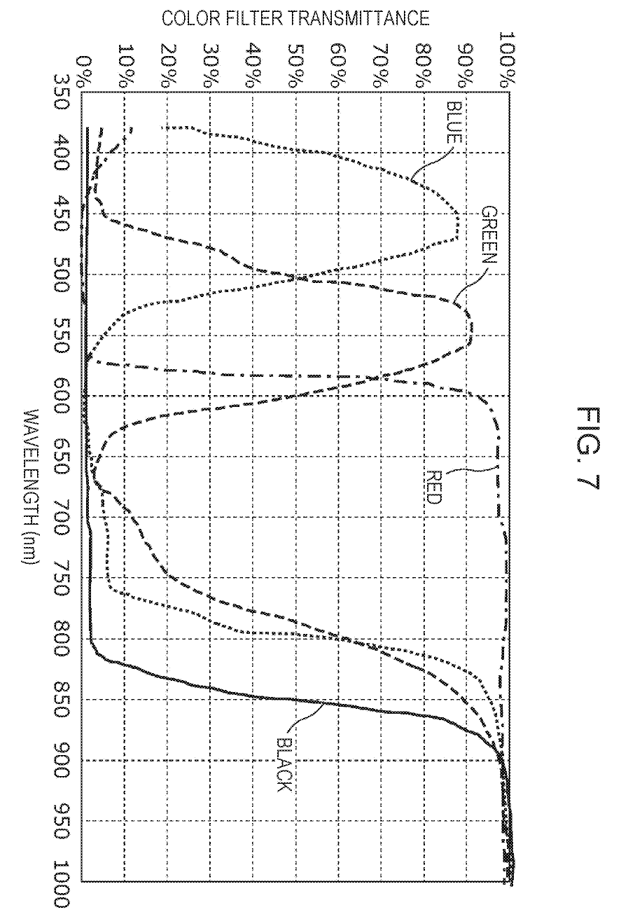

Next, the transmission characteristics of the color filters 60A and 60B are described. FIG. 7 is a diagram showing examples of the transmission spectra of color filters. FIG. 7 shows the transmission spectra of blue, green, red, and black color filters each deposited with a film thickness of 800 nm.

As the color filter 60A, for example, any of the blue, green, and red color filters is used. The visible light pixel 24 detects light of the color of the color filter used as the color filter 60A. As the color filter 60B, for example, any of the blue, green, and black color filters is used.

In the examples shown in FIG. 7, each of the blue, green, red, and black color filters transmits a component of a wavelength band of at least part of near-infrared light. The blue color filter transmits blue light and blocks visible light of the other wavelength bands. The green color filter transmits green light and blocks visible light of the other wavelength bands. The red color filter transmits red light and blocks visible light of the other wavelength bands. The black color filter has absorption in all wavelength bands of visible light and blocks visible light of all wavelength bands. The transmittance of light of a wavelength band that is blocked by a color filter is, for example, lower than or equal to 10%.

In the near-infrared light pixel 29, light transmitted through the color filter 60B and the photoelectric conversion layer 3 falls on the photodiode 10B. An aggregate average transmittance of the color filter 60B and the photoelectric conversion layer 3 with respect to all wavelength bands of visible light is, for example, lower than or equal to 6%. The aggregate average transmittance is an average transmittance in all wavelength bands of visible light in a case where visible light is transmitted through the color filter 60B and the photoelectric conversion layer 3, and can also be calculated by multiplying the transmittance of the color filter 60B by the transmittance of the photoelectric conversion layer 3. Since the aggregate average transmittance of the color filter 60B and the photoelectric conversion layer 3 with respect to all wavelength bands of visible light is lower than or equal to 6%, visible light is inhibited from falling on the photodiode 10B, so that there is improvement in wavelength separability of near-infrared light in the near-infrared light pixel 29. That is, near-infrared light can be imaged with a reduced visible light component. This makes it possible, for example, to bring about improvement in authentication accuracy in a case where data obtained by imaging near-infrared light is used in face authentication or other types of authentication.

In the photoelectric conversion layer 3 of the example shown in FIG. 6, the transmittance is 64% at 680 nm, which is a wavelength of a wavelength band of visible light at which the photoelectric conversion layer 3 has the lowest absorptance. Further, in the examples shown in FIG. 7, at 680 nm, the transmittance of the green color filter is 10%, the transmittance of the blue color filter 5%, and the transmittance of the black color filter 2%. Therefore, the aggregate transmittance of the green color filter and the photoelectric conversion layer 3 with respect to light at 680 nm is 6.4%. Further, the aggregate transmittance of the blue color filter and the photoelectric conversion layer 3 with respect to light at 680 nm is 3.2%. Further, the aggregate transmittance of the black color filter and the photoelectric conversion layer 3 with respect to light at 680 nm is 1.3%. By thus using any of the green, blue, and black color filters as the color filter 60B, the aggregate transmittance of the color filter 60B and the photoelectric conversion layer 3 is made lower than or equal to 7% even at 680 nm, at which the transmittance reaches its maximum, and can be made lower than or equal to 1% on average in all wavelength bands of visible light.

The transmission spectra of the color filters are not limited to the examples shown in FIG. 7 but can be adjusted according to the composition of photosensitive resin used in the formation of the color filters, the thicknesses of the color filters, or other factors.

### Another Example of Cross-sectional Structure of Pixels

Next, another example of a cross-sectional structure of a visible light pixel 24 and a near-infrared light pixel 29 according to the present embodiment is described. The following description of a cross-sectional structure of a visible light pixel 24 and a near-infrared light pixel 29 is given with a focus on points of difference from the foregoing description of a cross-sectional structure of a visible light pixel 24 and a near-infrared light pixel 29 with reference to FIG. 5, and a description of common features is omitted or simplified.

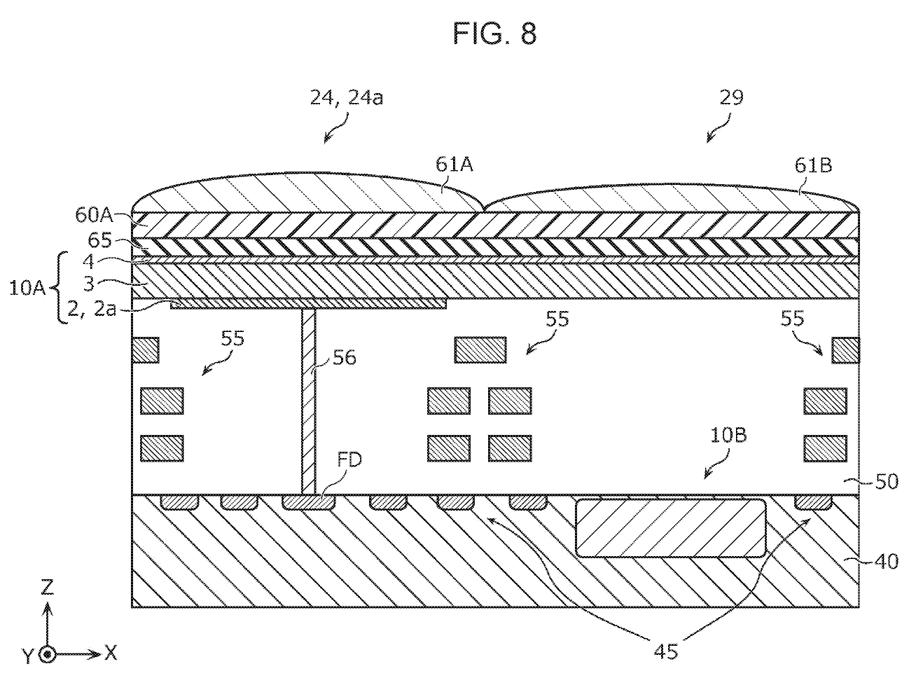

FIG. 8 is a cross-sectional view showing another example of a cross-sectional structure of a visible light pixel 24 and a near-infrared light pixel 29 according to the present embodiment. For viewability, FIG. 8 omits to illustrate hatching that indicates a cross-section of the insulating layer 50.

The example shown in FIG. 8 differs from the example shown in FIG. 5 mostly in that the visible light pixel 24a and the near-infrared light pixel 29 include microlenses 61A and 61B differing in curvature from each other and that the near-infrared light pixel 29 includes the color filter 60A.

In the example shown in FIG. 8, the visible light pixel 24a includes a microlens 61A in place of the microlens 61, and the near-infrared light pixel 29 includes a microlens 61B in place of the microlens 61. Although not illustrated, the visible light pixel 24b and the visible light pixel 24c include microlenses 61A in place of the microlenses 61.

The curvature of the microlens 61B is smaller than the curvature of the microlens 61A. Accordingly, the focal length of the microlens 61B is longer than the focal length of the microlens 61A. Therefore, the microlens 61A makes it easier to condense visible light onto the photoelectric conversion layer 3 located above the semiconductor substrate 40, and the microlens 61B makes it easier to condense near-infrared light onto the photodiode 10B formed in the semiconductor substrate 40, so that the sensitivity of each of the pixels can be increased. This also makes it harder for stray light to be generated, thus bringing about improvement in wavelength separability in each pixel.

Further, in the example shown in FIG. 8, the near-infrared light pixel 29 includes the color filter 60A in place of the color filter 60B. The color filter 60A lies astride the visible light pixel 24a and the near-infrared light pixel 29. In this case, the color filter 60A, which lies astride the visible light pixel 24a and the near-infrared light pixel 29, is, for example, a blue or green color filter. With this, even in a case where the photoelectric conversion layer 3 is low in absorptance in a wavelength band of part of red light, all wavelength bands of visible light that falls on the photodiode 10B are easily blocked by the photoelectric conversion layer 3 and the color filter 60A, as the blue or green color filter blocks red light. Further, using the same color filter 60A in the visible light pixel 24a and the near-infrared light pixel 29 makes it possible to use fewer types of material in patterning a color filter.

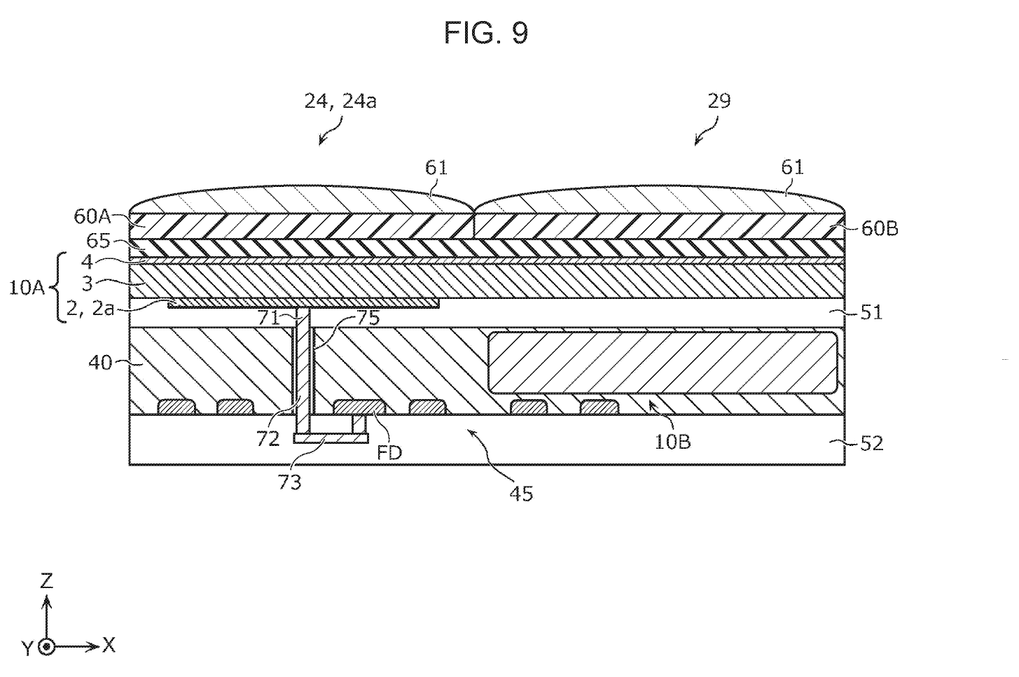

FIG. 9 is a cross-sectional view showing still another example of a cross-sectional structure of a visible light pixel 24 and a near-infrared light pixel 29 according to the present embodiment. For viewability, FIG. 9 omits to illustrate hatching that indicates cross-sections of insulating layers 51 and 52 and an insulating film 75.

The example shown in FIG. 9 differs from the example shown in FIG. 5 mostly in that the transistor group 45 is formed in a lower surface of the semiconductor substrate 40.

In the example shown in FIG. 9, the transistor group 45 is formed in the lower surface of the semiconductor substrate 40. This allows some transistors of the transistor group 45 to be placed below the photodiode 10B, making it possible to increase the area of the photodiode 10B in a plan view and increase the sensitivity of the near-infrared light pixel 29.

Further, in the example shown in FIG. 9, the insulating layer 51 is placed between the semiconductor substrate 40 and the pixel electrode 2 and between the semiconductor substrate 40 and the photoelectric conversion layer 3, and the insulating layer 52 is placed below the semiconductor substrate 40. Further, the impurity region FD is connected to the pixel electrode 2 via a via 71 placed in the insulating layer 51, a through-via 72 bored through the semiconductor substrate 40, and a wire 73 placed in the insulating layer 52. The insulating layer 75 is placed between the through-via 72 and the semiconductor substrate 40, so that the through-via 72 and the semiconductor substrate 40 are separate from each other. Further, although not illustrated, one or more wiring layers that can include wires, such as the aforementioned vertical signal lines 27, that connect the visible light pixels 24 and the near-infrared light pixels 29 to the peripheral circuit 15 or other wires are placed in the insulating layer 52.

### Another Example of Planar Layout of Pixels

Next, another example of a planar layout of visible light pixels 24 and near-infrared light pixels 29 according to the present embodiment is described. The following description of a planar layout of visible light pixels 24 and near-infrared light pixels 29 is given with a focus on points of difference from the foregoing description of a planar layout of visible light pixels 24 and near-infrared light pixels 29 with reference to FIG. 4, and a description of common features is omitted or simplified.

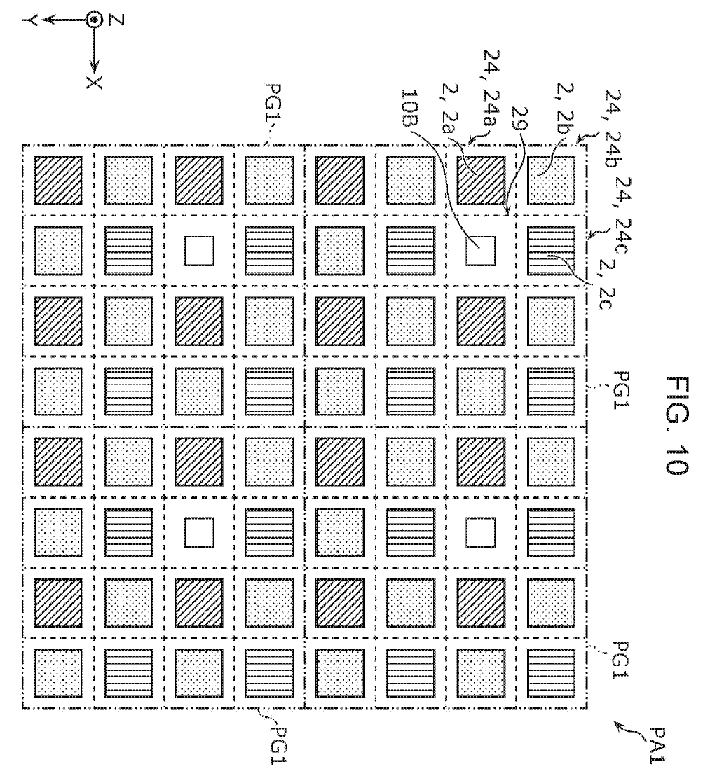

FIG. 10 is a plan view showing another example of a planar layout of visible light pixels 24 and near-infrared light pixels 29 according to the present embodiment. It should be noted that FIG. 10 omits to illustrate components other than pixel electrodes 2 and photodiodes 10B.

FIG. 10 shows a pixel array PA1 that is different in planar layout of visible light pixels 24 and near-infrared light pixels 29 from the pixel array PA. As is the case with the pixel array PA, the pixel array PA1 is constituted by a plurality of pixels and includes a plurality of visible light pixels 24a, a plurality of visible light pixels 24b, a plurality of visible light pixels 24c, and a plurality of near-infrared light pixels 29. The number of pixels that constitute the pixel array PA1 is not limited to particular numbers. The pixel array PA1 differs from the pixel array PA mostly in proportion of the near-infrared light pixels 29 in the plurality of pixels. The proportion of the near-infrared light pixels 29 in the plurality of pixels constituting the pixel array PA1 is lower than 25% and, in the example shown in FIG. 10, 6.25%. In other words, the pixel array PA1 includes more than three times as many visible light pixels 24 as near-infrared light pixels 29 and, in the example shown in FIG. 10, fifteen times as many visible light pixels 24 as near-infrared light pixels 29. This makes it possible to image near-infrared light while reducing deterioration of the resolution of a visible light image.

Further, in the example shown in FIG. 10, the pixel array PA1 includes a plurality of pixel groups PG1 each including visible light pixels 24a, 24b, and 24c and a near-infrared light pixel 29. In the example shown in FIG. 10, each of the pixel groups PG1 is composed of sixteen pixels including four visible light pixels 24a, seven visible light pixels 24b, four visible light pixels 24c, and one near-infrared light pixel 29. The arrangements of pixels in the plurality of pixel groups PG1 are the same as one another. The plurality of pixel groups PG1 are two-dimensionally arranged in a plan view. The two-dimensional arrangement of the plurality of pixel groups PG1 forms, for example, a Bayer arrangement part of which is replaced by near-infrared light pixels 29.

FIG. 11 is a plan view showing still another example of a planar layout of visible light pixels 24 and near-infrared light pixels 29 according to the present embodiment. It should be noted that FIG. 11 omits to illustrate components other than pixel electrodes 2 and photodiodes 10B.

FIG. 11 shows a pixel array PA2 that is different in planar layout of visible light pixels 24 and near-infrared light pixels 29 from the pixel array PA. As is the case with the pixel array PA, the pixel array PA2 is constituted by a plurality of pixels and includes a plurality of visible light pixels 24a, a plurality of visible light pixels 24b, a plurality of visible light pixels 24c, and a plurality of near-infrared light pixels 29. The number of pixels that constitute the pixel array PA2 is not limited to particular numbers. The pixel array PA2 differs from the pixel array PA mostly in shape of areas corresponding to the visible light pixels 24. In the pixel array PA2, the shapes of the areas corresponding to the visible light pixels 24 are octagons. In the pixel array PA2, one near-infrared light pixel 29 is located centrally among four visible light pixels 24 arranged in two rows and two columns. Further, in the pixel array PA2, areas corresponding to the near-infrared light pixels 29 are smaller than the areas corresponding to the visible light pixels 24.

In the pixel array PA2, pixel groups (in FIG. 11, chain double-dashed lines indicating the boundaries between the pixel groups are omitted) each composed of four visible light pixels 24 arranged in two rows and two columns and one near-infrared light pixel 29 located centrally among the four visible light pixels 24 are two-dimensionally arranged in a plan view. Although, in the example shown in FIG. 11, there is a place where no near-infrared light pixel 29 is placed centrally among four visible light pixels 24 arranged in two rows and two columns, a near-infrared light pixel 29 may be placed in the place. In this case, pixel groups each composed of one visible light pixel 24 and one near-infrared light pixel 29 that is adjacent to the one visible light pixel 24 are two-dimensionally arranged in a plan view.

### Modification 1

The following describes Modification 1 of Embodiment 1. Modification 1 is described below with a focus on points of difference from Embodiment 1, and a description of common features is omitted or simplified.

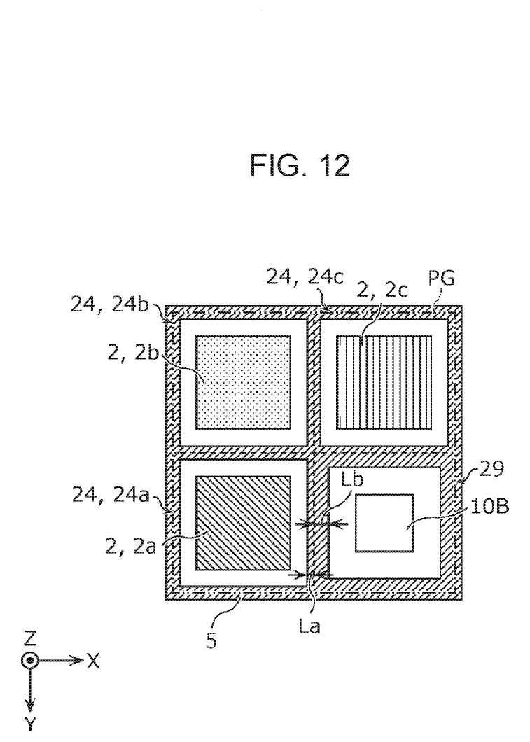

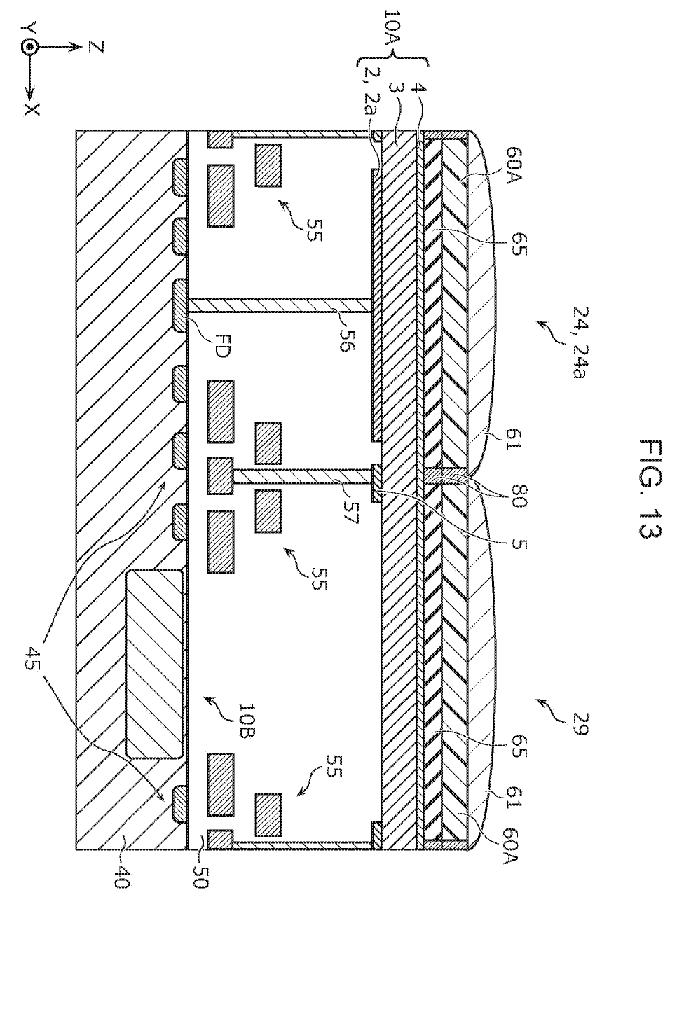

FIG. 12 is a plan view showing an example of a planar layout of visible light pixels 24 and a near-infrared light pixel 29 according to the present modification. FIG. 13 is a cross-sectional view showing an example of a cross-sectional structure of a visible light pixel 24 and a near-infrared light pixel 29 according to the present modification. It should be noted that FIG. 12 omits to illustrate components other than pixel electrodes 2, a photodiode 10B, and a shield electrode 5. Further, FIG. 12 shows one pixel group PG as a representative. Further, for viewability, FIG. 13 omits to illustrate hatching that indicates a cross-section of the insulating layer 50.

As shown in FIGS. 12 and 13, the imaging device according to the present modification differs from the imaging device 100 according to Embodiment 1 mostly in that the imaging device according to the present modification further includes the shield electrode 5, a via 57, and a light blocking structure 80.

As shown in FIG. 12, in a plan view, the shield electrode 5 is located between the pixel electrodes 2 of two adjacent visible light pixels 24 and between the photodiode 10B of a near-infrared light pixel 29 and a visible light pixel 24 that is adjacent to the near-infrared light pixel 29. In the example shown in FIG. 12, in a plan view, the shield electrode 5 is in gridlike fashion to individually surround the pixel electrodes 2 and the photodiode 10B. In a plan view, the shield electrode 5 is separate from the pixel electrodes 2 and the photodiode 10B and does not overlap the pixel electrodes 2 and the photodiode 10B. Alternatively, in a plan view, the shield electrode 5 may overlap part of the photodiode 10B.

For example, the shield electrode 5 is continuously formed en bloc in a photosensitive area in which the pixel array PA is placed. The shield electrode 5 may be divided into parts provided in correspondence with one or more pixels included in the pixel array PA.

The shield electrode 5 is connected, for example, to a voltage supply circuit or a ground (both not illustrated) and retained at a predetermined potential. The shield electrode 5 is, for example, at the same potential in the pixel array PA. The shield electrode 5 and the pixel electrodes 2 are electrically separated. The potential of the shield electrode 5 is, for example, a fixed potential but may be varied.

The shield electrode 5 reduces electrical mixture of colors between adjacent visible light pixels 24. Further, the shield electrode 5 inhibits signal charge generated by the photoelectric conversion layer 3 in a near-infrared light pixel 29 that is adjacent to a visible light pixel 24 from migrating to the visible light pixel 24. In a case where the signal charge is a hole, the potential of the shield electrode 5 is set, for example, to be higher than the potential of the charge accumulation node 34 at which the signal charge is reset. This makes it possible to inhibit the signal charge from migrating to the adjacent visible light pixel 24 and highly efficiently take out signal charge generated near the shield electrode 5, bringing about improvement in sensitivity. The potential of the shield electrode 5 may be set to be lower than the potential of the charge accumulation node 34 at which the signal charge is reset. This also causes the signal charge to be trapped by the shield electrode 5 and makes it possible to inhibit the signal charge from migrating to the adjacent visible light pixel 24.

Further, as shown in FIG. 13, the shield electrode 5 is located below the photoelectric conversion layer 3 i.e. at a side that faces away from the optical incidence side. Further, the shield electrode 5 is also located above the semiconductor substrate 40. Therefore, the shield electrode 5 is located between the semiconductor substrate 40 and the photoelectric conversion layer 3. Further, in a plan view, the shield electrode 5 overlaps part of the transistor group 45.

The shield electrode 5 has a light blocking effect on visible light and near-infrared light. By part of the transistor group 45 being covered with the light blocking shield electrode 5 from above, light is inhibited from falling on the transistor group 45, so that generation of noise due to absorption of light by the transistor group 45 can be reduced. The shield electrode 5 may reflect visible light and near-infrared light transmitted through the photoelectric conversion layer 3. The shield electrode 5 is formed from a metal such as aluminum, copper, or tungsten, from a metal nitride, from polysilicon rendered conductive by being doped with impurities, or from other substances. For example, the shield electrode 5 does not transmit 90% or more of visible light and near-infrared light falling thereon. The shield electrode 5 may not transmit 99% or more of visible light and near-infrared light falling thereon.

Further, in the example shown in FIG. 12, in a plan view, the shield electrode 5 is placed in a position including the boundaries between two adjacent pixels. In the example shown in FIG. 12, in a plan view, the width of a portion of the shield electrode 5 located between the photodiode 10B of a near-infrared light pixel 29 and the pixel electrode 2 of a visible light pixel 24 that is adjacent to the near-infrared light pixel 29 is wider than a portion of the shield electrode 5 located between the pixel electrodes 2 of two adjacent visible light pixels 24. In the example shown in FIG. 12, in a plan view, the shield electrode 5 is configured such that in a portion of the shield electrode 5 located between the photodiode 10B of a near-infrared light pixel 29 and the pixel electrode 2 of a visible light pixel 24 that is adjacent to the near-infrared light pixel 29, a width Lb of an area that is closer to the photodiode 10B of the near-infrared light pixel 29 than is the position of the boundary between the two adjacent pixels is longer than a width La of an area that is closer to the pixel electrode 2 of the visible light pixel 24 than is the position of the boundary. Accordingly, in an area corresponding to the near-infrared light pixel 29 in which no light blocking pixel electrode 2 is placed, the light blocking shield electrode 5 is placed in a larger proportion. This further inhibits light from falling on the transistor group 45 in the near-infrared light pixel 29.

The shield electrode 5 is, for example, made of the same material as the pixel electrodes 2 and formed in the same plane en bloc in the same step as the pixel electrodes 2. Alternatively, the shield electrode 5 and the pixel electrode 2 may be made of different materials. Further, the step of forming the shield electrode 5 and the step of forming the pixel electrodes 2 may be separate from each other.

As shown in FIG. 13, the via 57 is connected to the shield electrode 5. The via 57 is a plug formed from a metal such as aluminum, copper, or tungsten, from a metal nitride, from polysilicon rendered conductive by being doped with impurities, or from other substances. In the example shown in FIG. 13, the via 57 connects the shield electrode 5 to a metal layer 55. For example, the metal layer 55 connected to the via 57 is a wiring layer, and the shield electrode 5 is connected via the metal layer 55 to the voltage supply circuit or the ground (both not illustrated). In the example shown in FIG. 13, the via 57 is connected to one of the plurality of metal layers 55 that is closest to the semiconductor substrate 40.

As shown in FIG. 13, the via 57 is located between the shield electrode 5 and the semiconductor substrate 40 in the stack direction. Further, the via 57 is located between the pixel electrode 2a and the photodiode 10B in a plan view. Although not illustrated, not only one via 57 but a plurality of the vias 57 may be connected to the shield electrode 5. For example, the plurality of vias 57 may be arranged between the pixel electrode 2a and the photodiode 10B in a plan view. Further, for example, in a plan view, a via 57 may be placed also between the photodiode 10B of a near-infrared light pixel 29 and the pixel electrode 2 of a visible light pixel 24 other than a visible light pixel 24a that is adjacent to the near-infrared light pixel 29. Further, for example, in a plan view, a via 57 may be placed also between the pixel electrodes 2 of two adjacent visible light pixels 24.

The via 57 has a light blocking effect on visible light and near-infrared light. This causes light falling obliquely on the near-infrared light pixel 29 to be blocked by the via 57 and inhibits the light from falling on a portion of the transistor group 45 that faces the visible light pixel 24a, thus making it possible to reduce generation of noise due to absorption of light by the transistor group 45. This also inhibits near-infrared light traveling through between the pixel electrode 2a and the shield electrode 5 from falling on the photodiode 10B, thus making it possible to reduce mixture of colors between pixels. Further, the via 57 may reflect near-infrared light transmitted through the photoelectric conversion layer 3. This increases the amount of near-infrared light that falls on the photodiode 10B, thus making it possible to increase the sensitivity of the near-infrared light pixel 29.

As shown in FIG. 13, the light blocking structure 80 is located above the photoelectric conversion layer 3, i.e. closer to the optical incidence side than is the photoelectric conversion layer 3. In the example shown in FIG. 13, the light blocking structure 80 is formed in both the passivation layer 65 and the color filter 60A. The light blocking structure 80 blocks visible light and near-infrared light. The light blocking structure 80 may reflect visible light and near-infrared light. The light blocking structure 80 is, for example, a metal grid or an air gap. In a case where the light blocking structure 80 is an air gap, a surface that is in contact with the air gap reflects visible light and near-infrared light, whereby the visible light and the near-infrared light are blocked. Alternatively, the light blocking structure 80 is formed in either the passivation layer 65 or the color filter 60A. Further, although, in the example shown in FIG. 13, both the visible light pixel 24a and the near-infrared light pixel 29 include the color filter 60A, the near-infrared light pixel 29 may include the aforementioned color filter 60B in place of the color filter 60A. In this case, for example, the light blocking structure 80 is formed between the color filter 60A and the color filter 60B.

Further, as shown in FIG. 13, the light blocking structure 80 is located between the pixel electrode 2a and the photodiode 10B in a plan view. This causes part of the transistor group 45 to be covered with the light blocking structure 80 from above and inhibits light from falling on the transistor group 45, thus making it possible to reduce generation of noise due to absorption of light by the transistor group 45. Further, in a plan view, the light blocking structure 80 may also be placed between the photodiode 10B of a near-infrared light pixel 29 and the pixel electrode 2 of a visible light pixel 24 other than a visible light pixel 24a that is adjacent to the near-infrared light pixel 29. Further, for example, in a plan view, the light blocking structure 80 may also be placed between the pixel electrodes 2 of two adjacent visible light pixels 24. Although not illustrated, the light blocking structure 80 extends along the boundary between two adjacent pixels (specifically, in the example shown in FIG. 13, the boundary between the visible light pixel 24a and the near-infrared light pixel 29), for example, in a plan view. Further, by blocking and reflecting light falling obliquely on an area near the boundary between two adjacent pixels, the light blocking structure 80 can bring about improvement in wavelength separability and sensitivity in each pixel.

In the example shown in FIG. 13, at least one of the plurality of metal layers 55 is located between the pixel electrode 2 and the shield electrode 5 in a plan view. This causes part of the transistor group 45 in the visible light pixel 24 to be covered with the metal layer 55. Further, in the example shown in FIG. 13, at least one of the plurality of metal layers 55 is located between the photodiode 10B and the shield electrode 5 in a plan view. This causes part of the transistor group 45 in the near-infrared light pixel 29 to be covered with the metal layer 55. Further, in a plan view, the transistor group 45 may be completely covered with a metal structure group having a light blocking effect on visible light and near-infrared light. This metal structure group includes, for example, at least one of the pixel electrode 2, the shield electrode 5, the metal grid, and the metal layer 55.

Further, in the example shown in FIG. 13, the metal layer 55 located between the pixel electrode 2 and the shield electrode 5 in a plan view and the metal layer 55 located between the photodiode 10B and the shield electrode 5 in a plan view may be located below a middle position that is between the upper surface of the semiconductor substrate 40 and the lower surface of the photoelectric conversion layer 3 in the stack direction. This inhibits light falling obliquely on the visible light pixel 24 and the near-infrared light pixel 29 from falling on the transistor group 45.

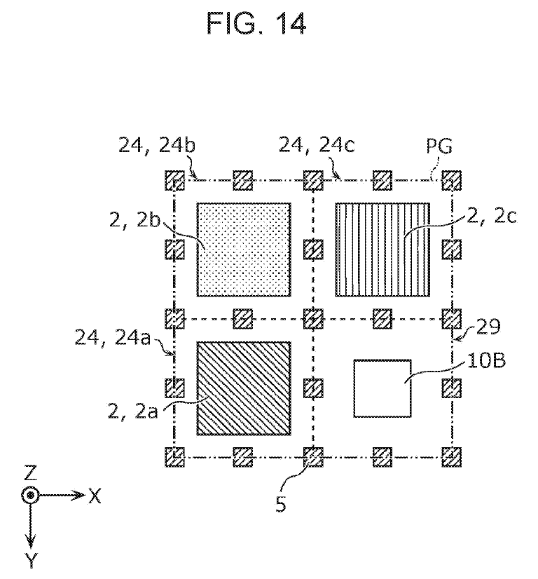

Although, in the example shown in FIG. 12, the shield electrode 5 is continuously formed en bloc to surround the pixel electrodes 2 and the photodiode 10B in a plan view, this is not intended to impose any limitation. For example, the shield electrode 5 may be divided into a plurality of shield electrodes 5 as shown in FIG. 14. FIG. 14 is a plan view showing another example of a planar layout of visible light pixels 24 and a near-infrared light pixel 29 according to the present modification. It should be noted that FIG. 14 omits to illustrate components other than pixel electrodes 2, a photodiode 10B, and shield electrodes 5. Further, FIG. 14 shows one pixel group PG as a representative.

As shown in FIG. 14, the plurality of shield electrodes 5 divided from each other are arranged along the boundaries between two adjacent pixels. The plurality of shield electrodes 5 are arranged to individually surround the pixel electrodes 2 and the photodiode 10B. In the example shown in FIG. 14, in a plan view, the plurality of shield electrodes 5 are placed not only between the pixel electrodes 2 of two adjacent visible light pixels 24 and between the photodiode 10B of a near-infrared light pixel 29 and the pixel electrode 2 of a visible light pixel 24 that is adjacent to the near-infrared light pixel 29 but also between pixel electrodes 2 that are diagonally arranged and between a photodiode 10B and a pixel electrode 2 that are diagonally arranged. The number and placement of the plurality of shield electrodes 5 are not limited to the example shown in FIG. 14. Further, although, in the example shown in FIG. 14, the plurality of shield electrodes 5 each have the shape of a square in a plan view, the plurality of shield electrodes 5 may each have another shape in a plan view. Although not illustrated, vias 57 are connected separately to each of the plurality of shield electrodes 5.

### Modification 2

The following describes Modification 2 of Embodiment 1. Modification 2 is described below with a focus on points of difference from Embodiment 1 and Modification 1, and a description of common features is omitted or simplified.

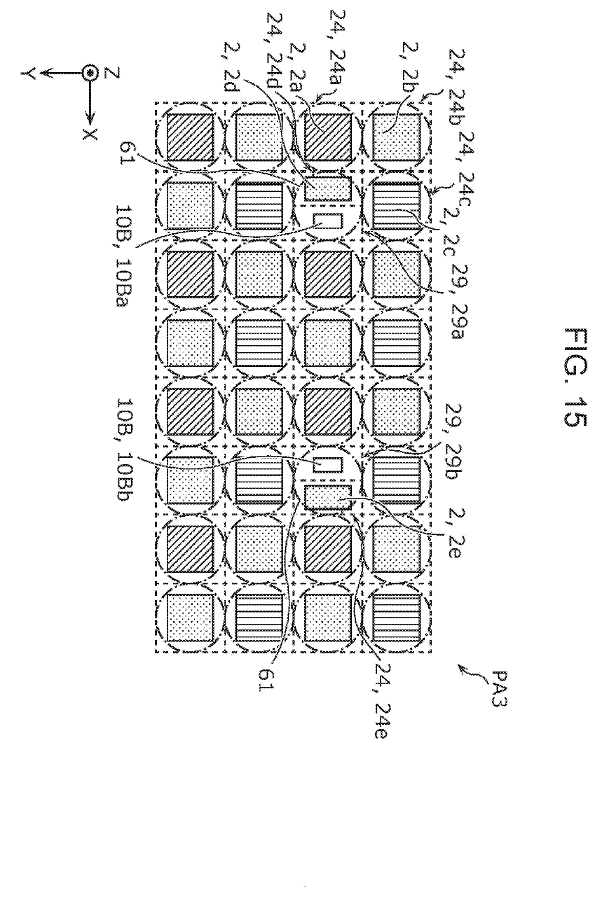

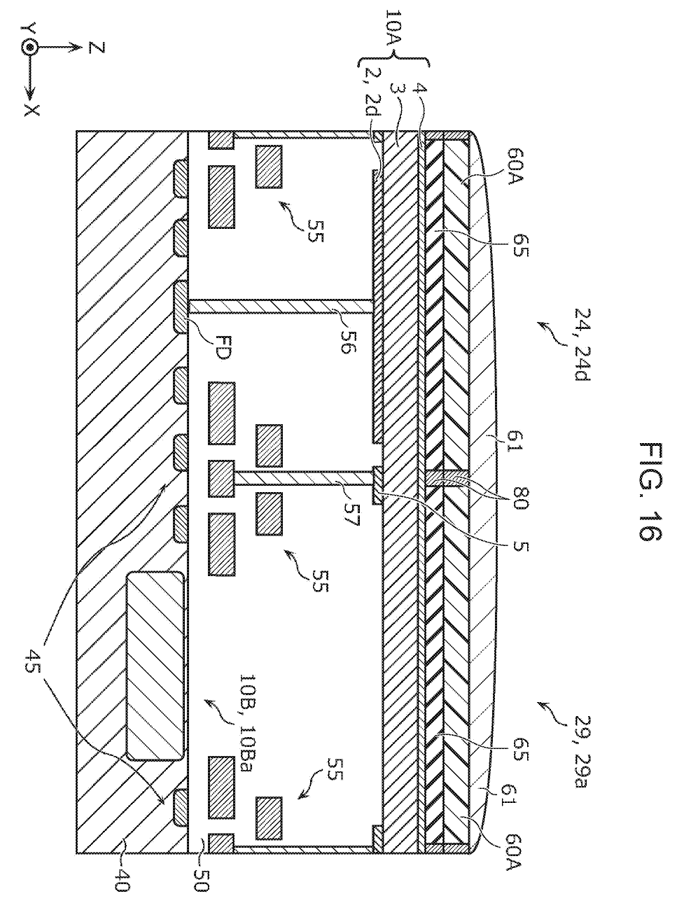

FIG. 15 is a plan view showing an example of a planar layout of visible light pixels 24 and near-infrared light pixels 29 according to the present modification. FIG. 16 is a cross-sectional view showing an example of a cross-sectional structure of a visible light pixel 24 and a near-infrared light pixel 29 according to the present modification. It should be noted that FIG. 15 omits to illustrate components other than pixel electrodes 2, photodiodes 10B, and microlenses 61. Further, FIG. 15 shows the microlenses 61 with dot-and-dash lines. Further, for viewability, FIG. 16 omits to illustrate hatching that indicates a cross-section of the insulating layer 50.

As shown in FIGS. 15 and 16, the imaging device according to the present modification differs from the imaging devices according to Embodiment 1 and Modification 1 of Embodiment 1 mostly in that there are a visible light pixel 24 and a near-infrared light pixel 29 that share a microlens 61.

As shown in FIG. 15, the imaging device according to the present modification includes a pixel array PA3 constituted by a plurality of pixels including visible light pixels 24 and near-infrared light pixels 29. The pixel array PA3 differs from the pixel arrays according to Embodiment 1 and Modification 1 of Embodiment 1 in that the plurality of pixels constituting the pixel array PA3 include a visible light pixel 24d and a near-infrared light pixel 29a that share a microlens 61 and a visible light pixel 24e and a near-infrared light pixel 29b that share a microlens 61. In the present modification, the visible light pixels 24d and 24e are examples of first pixels, and the near-infrared light pixels 29a and 29b are examples of second pixels. If necessary, the visible light pixels 24 may be described herein with a distinction between the visible light pixels 24d and 24e, and the near-infrared light pixels 29 may be described herein with a distinction between the near-infrared light pixels 29a and 29b. Also, the pixel electrodes 2 of the visible light pixels 24 may be described with a distinction between a pixel electrode 2d of the visible light pixel 24d and a pixel electrode 2e of the visible light pixel 24e. Also, the photodiodes 10B of the near-infrared light pixels 29 may be described with a distinction between a photodiode 10Ba of the near-infrared light pixel 29a and a photodiode 10Bb of the near-infrared light pixel 29b. In the example shown in FIG. 15, the pixel electrodes 2d and 2e are patterned with dots, as the visible light pixels 24d and 24e are pixels including color filters of the same color as the visible light pixels 24b. The visible light pixels 24d and 24e may be pixels including color filters of the same color as the visible light pixels 24a or 24c.

As shown in FIG. 15, the plurality of pixels constituting the pixel array PA3 include visible light pixels 24a, 24b, and 24c as well as the visible light pixel 24d, the near-infrared light pixel 29a, the visible light pixels 24e, and the near-infrared light pixels 29b. Since the visible light pixel 24d and the near-infrared light pixel 29a share a microlens 61 and the visible light pixel 24e and the near-infrared light pixel 29b share a microlens 61, the sizes of areas corresponding to the visible light pixel 24d and the near-infrared light pixel 29a and the sizes of areas corresponding to the visible light pixel 24e and the near-infrared light pixel 29b are half as large as the sizes of areas corresponding to the visible light pixels 24a, 24b, and 24c, which are visible light pixels 24 other than the visible light pixels 24d and 24e. The plurality of pixels constituting the pixel array PA3 may also include a near-infrared light pixel 29 having a corresponding area of the same size as the visible light pixels 24a, 24b, and 24c.

As shown in FIG. 15, the pixel electrodes 2d and 2e and the photodiodes 10Ba and 10Bb are each eccentrically located in one predetermined direction from the center of the corresponding one of the microlenses 61 in a plan view. In the example shown in FIG. 15, the pixel electrode 2d and the photodiode 10Bb are each eccentrically located in a negative direction of the X axis from the center of the corresponding one of the microlenses 61 in a plan view and are each entirely displaced in the negative direction of the X axis from the center of the corresponding one of the microlenses 61. Further, in the example shown in FIG. 15, the pixel electrode 2e and the photodiode 10Ba are each eccentrically located in a positive direction of the X axis from the center of the corresponding one of the microlenses 61 in a plan view and are each entirely displaced in the positive direction of the X axis from the center of the corresponding one of the microlenses 61. It should be noted that the positive direction of the X axis is a direction opposite to the negative direction of the X axis.

The relative positions of the pixel electrode 2d and 2e are symmetrical with respect to the centers of the microlenses 61 in a plan view. The visible light pixel 24d and the visible light pixel 24e output signals that can be used in phase difference detection. The phase difference detection is, for example, performed by a processing circuit or other circuits in a camera system and utilized for autofocusing or other purposes. In this case, autofocusing is made possible with visible light of which a high-resolution image is taken. Further, the relative positions of the photodiodes 10Ba and 10Bb are symmetrical with respect to the centers of the microlenses 61 in a plan view. The near-infrared light pixel 29a and the near-infrared light pixel 29b output signals that can be used in phase difference detection. In this case, autofocusing is made possible with near-infrared light. The direction in which the pixel electrodes 2d and 2e and the photodiodes 10Ba and 10Bb are each eccentrically located from the center of the corresponding one of the microlenses 61 is not limited to the X-axis direction but may be, for example, the Y-axis direction.

Further, as shown in FIG. 16, a cross-sectional structure of portions of the visible light pixel 24d and the near-infrared light pixel 29a that are lower than the microlens 61 is, for example, the same as the example shown in FIG. 13. As shown in FIG. 16, a shield electrode 5 placed between the pixel electrode 2d and the photodiode 10Ba in a plan view inhibits signal charge generated by the photoelectric conversion layer 3 in the near-infrared light pixel 29a that is adjacent to the visible light pixel 24d from migrating to the visible light pixel 24d. This makes it possible to increase the accuracy of phase difference detection involving the use of signals outputted by the visible light pixel 24d and the near-infrared light pixel 29a. It should be noted that the cross-sectional structure of the visible light pixel 24d and the near-infrared light pixel 29a is not limited to the example shown in FIG. 16. The cross-sectional structure of the portions of the visible light pixel 24d and the near-infrared light pixel 29a that are lower than the microlens 61 may be the same as the example shown in FIG. 5, 8, or 9. Further, although FIG. 16 shows the cross-sectional structure of the visible light pixel 24d and the near-infrared light pixel 29a, a cross-sectional structure of the visible light pixel 24e and the near-infrared light 29b may be a structure obtained by causing the visible light pixel 24d and the near-infrared light pixel 29a to swap positions with each other (i.e. a structure inverted along the X axis).

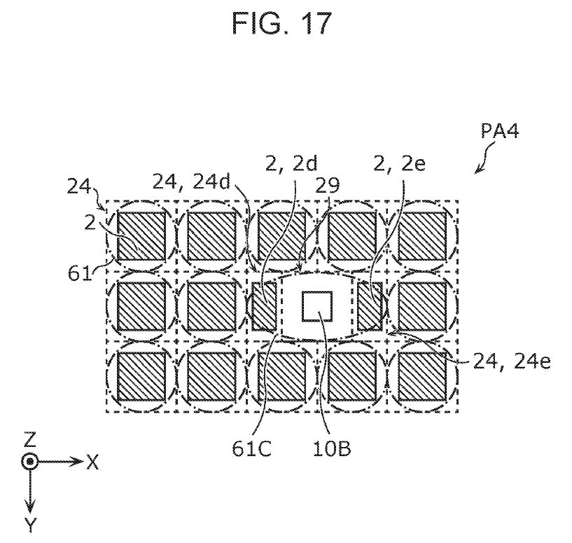

Although, in the example shown in FIG. 15, one visible light pixel 24d and one near-infrared light pixel 29a share a microlens 61 and one visible light pixel 24e and one near-infrared light pixel 29b share a microlens 61, this is not intended to impose any limitation. FIG. 17 is a plan view showing another example of a planar layout of visible light pixels 24 and a near-infrared light pixel 29 according to the present modification. It should be noted that FIG. 17 omits to illustrate components other than pixel electrodes 2, a photodiode 10B, and microlenses 61 and 61C. Further, FIG. 17 shows the microlenses 61 and 61C with dot-and-dash lines. Further, although FIG. 17 illustrates the visible light pixels 24 other than the visible light pixel 24d and the visible light pixel 24e with no distinction, the visible light pixels 24 other than the visible light pixel 24d and the visible light pixel 24e may be visible light pixels 24a, 24b, or 24c.

As shown in FIG. 17, the imaging device according to the present modification may include a pixel array PA4 in place of the pixel array PA3. The pixel array PA4 is constituted by a plurality of pixels including a plurality of visible light pixels 24 including visible light pixels 24d and 24e and a near-infrared light pixel 29. The visible light pixels 24d and 24e and the near-infrared light pixel 29 share a microlens 61C. The plurality of pixels constituting the pixel array PA4 may include a near-infrared light pixel 29 that does not share a microlens with the visible light pixels 24d and 24e.

In the example shown in FIG. 17, the length of the microlens 61C in the X-axis direction is longer than that of a microlens 61 or, more particularly, twice as long as that of a microlens 61. In the example shown in FIG. 17, the sizes of areas corresponding to the visible light pixels 24d and 24e are half as large as the sizes of areas corresponding to visible light pixels 24 other than the visible light pixels 24d and 24e, and the size of an area corresponding to the near-infrared light pixel 29 is equal to the sizes of the areas corresponding to the visible light pixels 24 other than the visible light pixels 24d and 24e. In the example shown in FIG. 17, since the area corresponding to the near-infrared light pixel 29 can be made larger than areas corresponding to the near-infrared light pixels 29a and 29b shown in FIG. 15, the sensitivity to near-infrared light can be improved.

As shown in FIG. 17, the pixel electrodes 2d and 2e are each eccentrically located in one predetermined direction from the center of the microlens 61C in a plan view. In the example shown in FIG. 17, the pixel electrode 2d is eccentrically located in a negative direction of the X axis from the center of the microlens 61C in a plan view and is entirely displaced in the negative direction of the X axis from the center of the microlens 61C. Further, in the example shown in FIG. 17, the pixel electrode 2e is eccentrically located in a positive direction of the X axis from the center of the microlens 61C in a plan view and is entirely displaced in the positive direction of the X axis from the center of the microlens 61C. The pixel electrode 2d and 2e are placed in positions that are symmetrical with respect to the center of the microlens 61C in a plan view. The visible light pixel 24d and the visible light pixel 24e output signals that can be used in phase difference detection.

### Embodiment 2

Next, Embodiment 2 is described. Embodiment 2 describes a camera system including the imaging device according to Embodiment 1, Modification 1 of Embodiment 1, or Modification 2 of Embodiment 1.

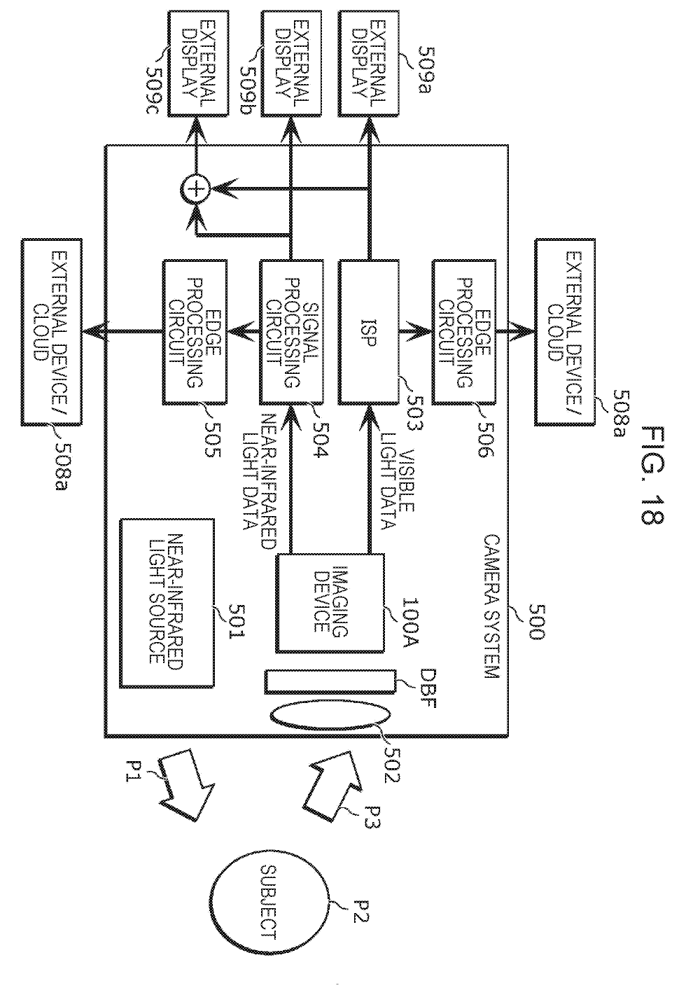

FIG. 18 is a block diagram showing an example of a configuration of a camera system 500 according to the present embodiment.

The camera system 500 includes an imaging device 100A, a near-infrared light source 501, a lens optical system 502, an ISP (image signal processor) 503, a signal processing circuit 504, an edge processing circuit 505, an edge processing circuit 506, and a double band-pass filter DBF. The camera system 500 can be, for example, a smartphone, a digital camera, a video camera, an on-board camera, or other cameras. The camera system 500 is configured to process data based on two wavelength bands of light obtained by the imaging device 100A and output the data to an external device. The ISP 503, the signal processing circuit 504, the edge processing circuit 505, and the edge processing circuit 506 may each be constituted by individual circuits, or at least one of the ISP 503, the signal processing circuit 504, the edge processing circuit 505, and the edge processing circuit 506 may share at least some circuits. The camera system 500 may perform centralized processing or may perform decentralized processing.

The near-infrared light source 501 emits near-infrared light P1 toward a subject P2. The near-infrared light source 501 is an example o a light source. The subject P2 is an example of an object. The near-infrared light source 501 emits the near-infrared light P1, for example, in a band of wavelengths that the photoelectric conversion layer 3 does not absorb.

The imaging device 100A receives, through the lens optical system 502 and the double band-pass filter DBF, reflected light P3 produced by the subject P2 reflecting the near-infrared light P1 emitted by the near-infrared light source 501, and detects the reflected light P3. For example, the imaging device 100A dually outputs data based on visible light and data based on near-infrared light. The imaging device 100A is, for example, the imaging device according to Embodiment 1, Modification 1 of Embodiment 1, or Modification 2 of Embodiment 1.

The lens optical system 502 may include, for example, a lens group including at least either an autofocus lens or a zoom lens and a diaphragm. The lens optical system 502 condenses light onto an imaging surface of the imaging device 100A. The imaging surface of the imaging device 100A is, for example, the aforementioned photosensitive area. The double band-pass filter DBF is located at an optical incidence side of the imaging device 100A and has transmitting regions in both a wavelength band of visible light and a wavelength band of near-infrared light. Further, the double band-pass filter DBF has a light blocking region in a wavelength band between the transmitting region in the wavelength band of visible light and the transmitting region in the wavelength band of near-infrared light. On the photoelectric conversion layer 3, visible light and near-infrared light transmitted through the double band-pass filter DBF fall. This brings about improvement in wavelength separability of visible light and near-infrared light in the visible light pixel 24 and the near-infrared light pixel 29. The double band-pass filter DBF is, for example, a thin-film stacked filter.

In the example shown in FIG. 18, the double band-pass filter DBF is placed between the imaging device 100A and the lens optical system 502, and the reflected light P3 transmitted through the lens optical system 502 falls on the double band-pass filter DBF. The double band-pass filter DBF is not limited to particular ones as long as it is placed closer to the optical incidence side than is the photoelectric conversion layer 3. For example, the double band-pass filter DBF may be paced at an optical incidence side of the lens optical system 502. Further, the double band-pass filter DBF may be placed within the imaging device 100A.

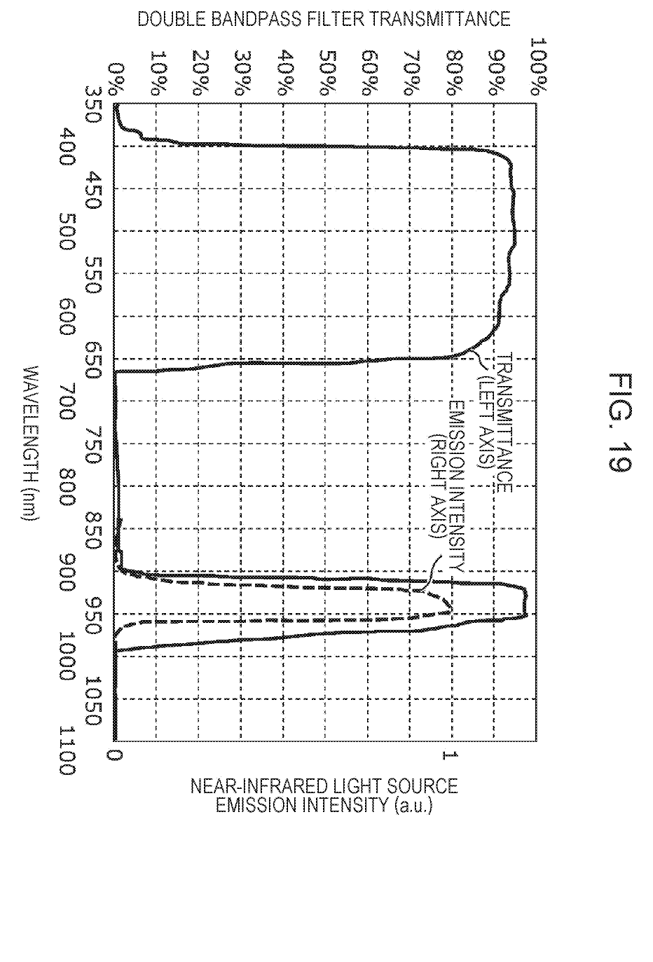

The transmission spectrum of the double band-pass filter DBF and the emission spectrum of the near-infrared light source 501 are described here. FIG. 19 is a diagram showing an example of the transmission spectrum of a double band-pass filter DBF and an example of the emission spectrum of a near-infrared light source 501 according to the present embodiment. In FIG. 19, the transmission spectrum of the double band-pass filter DBF is indicated by a solid line, and the emission spectrum of the near-infrared light source 501 is indicated by a dashed line.

In the examples shown in FIG. 19, the double band-pass filter DBF has transmission regions in a wavelength band of visible light of 400 nm to 650 nm and a wavelength band of near-infrared light including 940 nm. A boundary wavelength on a long wavelength side of the transmitting region of visible light through the double band-pass filter DBF is, for example, longer than or equal to 630 nm and shorter than or equal to 670 nm. This makes it harder for a wavelength of approximately 680 nm, which is low in visibility, to reach the photoelectric conversion layer 3, thus making it possible to output a naturally colored image that is close to actual appearance. This also brings about further improvement in wavelength separability of near-infrared light in the near-infrared light pixel 29. A boundary wavelength on a short wavelength side of the transmitting region of visible light through the double band-pass filter DBF is, for example, longer than or equal to 380 nm and shorter than or equal to 420 nm.

In the examples shown in FIG. 19, the near-infrared light P1 emitted by the near-infrared light source 501 has a narrowband emission peak in the transmitting region of near-infrared light through the double band-pass filter DBF or, specifically, at 940 nm. This makes it possible to block ambient light in a band of wavelengths other than the wavelength of the near-infrared light P1 from the near-infrared light source 501, thus bringing about improvement in robustness in sensing. The near-infrared light source 501 is, for example, a VCSEL (vertical cavity surface emitting laser) lighting that emits near-infrared light P1 having a narrowband emission peak at approximately 940 nm. A half-width of the emission peak of the near-infrared light P1 is, for example, less than or equal to 70 nm. The half-width of the emission peak of the near-infrared light P1 may be less than or equal to 50 nm. The near-infrared light source 501 is not limited to particular lighting but may be LED (light-emitting diode) lighting or laser diode lighting. Further, the center of the transmitting region of near-infrared light through the double band-pass filter DBF and the emission peak of the near-infrared light P1 emitted by the near-infrared light source 501 are not limited to being approximately 940 nm but are designed for any purpose. The center of the transmitting region of near-infrared light through the double band-pass filter DBF and the emission peak of the near-infrared light P1 emitted by the near-infrared light source 501 may be, for example, approximately 850 nm. Further, the transmitting region of near-infrared light through the double band-pass filter DBF and the emission band of the near-infrared light P1 emitted by the near-infrared light source 501 may include a band of wavelengths of 850 nm to 940 nm.

With continued reference to FIG. 18, the ISP 503 processes data based on visible light. This gives a full-color image. The full-color image is, for example, transmitted to and displayed on an external display 509a. Further, the fill-color image is, for example, transmitted to an external device and/or a cloud 508a after being processed by the edge processing circuit 506.

The signal processing circuit 504 processes the data based on near-infrared light. This gives an image based on near-infrared light. For example, the signal processing circuit 504 may be configured to calculate, from the data based on near-infrared light, the distance to the subject. In this case, for example, the imaging device 100A has a circuit configuration for performing ranging by a TOF (time-of-flight) method. The image based on near-infrared light is transmitted to and displayed on an external display 509b. Further, the image based on near-infrared light is transmitted to an external device and/or a cloud 508a after being processed by the edge processing circuit 505. Further, the full-color image and the image based on near-infrared light can be added together and displayed on an external display 509c. Although, in the example shown in FIG. 18, the images are outputted from the camera system 500 separately to each of the external displays 509a, 509b, and 509c, the images may be outputted to one external display.

Further, it is also possible to perform sensing using the data based on visible light and the data based on near-infrared light. Since the data based on visible light and the data based on near-infrared light are obtained by one imaging device 100A, image processing can be easily done without misaligned images. Examples of the sensing include authentication represented by face authentication, machine vision shape recognition, and sensing at a specific near-infrared such as moisture detection. For example, the sensing may be performed by a processing circuit (not illustrated) of the camera system 500 or may be performed by the external device and/or the cloud 508a.

### Other Embodiments

While the foregoing has described an imaging device and a camera system according to the present disclosure with reference to embodiments, the present disclosure is not intended to be limited to these embodiments. Various modifications conceived of by persons skilled in the art without departing from the spirit of the present disclosure are encompassed in the scope of the present disclosure. Further, constituent elements in the embodiments and modifications of the embodiments may be arbitrarily combined without departing from the spirit of the present disclosure.

For example, although, in the foregoing embodiments, the transfer transistor 18, the amplifying transistor 21, the reset transistor 22, and the address transistor 23 are N-channel MOSFETs, this is not intended to impose any limitation. At least one of the transfer transistor 18, the amplifying transistor 21, the reset transistor 22, and the address transistor 23 may be a P-channel MOSFET. Further, at least one of the transfer transistor 18, the amplifying transistor 21, the reset transistor 22, and the address transistor 23 may be not a field-effect transistor but another transistor such as a bipolar transistor.

An imaging device and a camera system according to the present disclosure can be used in a camera for use in a smartphone, a camera for use in a tablet, a camera for use in a laptop computer, a camera for medical use, a camera for use in a robot, a security camera, a camera that is mounted on a vehicle for use, or other cameras.

What is claimed is:

1. An imaging device comprising:
at least one first pixel;
at least one second pixel that is adjacent to the at least one first pixel in a plan view; and
a photoelectric conversion layer that lies astride the at least one first pixel and the at least one second pixel, that is shared by the at least one first pixel and the at least one second pixel, and that absorbs visible light, wherein
the at least one first pixel includes a first pixel electrode that collects first signal charge generated by the photoelectric conversion layer and that has a light blocking effect on the visible light and near-infrared light, and
the at least one second pixel includes a photodiode that generates second signal charge by absorbing the near-infrared light transmitted through the photoelectric conversion layer.

2. The imaging device according to claim 1, wherein the at least one second pixel includes a color filter that is located above a surface of the photoelectric conversion layer on which light is incident, that transmits a component of a wavelength band of at least part of the near-infrared light, and that blocks a component of a wavelength band of at least part of the visible light.

3. The imaging device according to claim 2, wherein an aggregate average transmittance of the color filter of the at least one second pixel and the photoelectric conversion layer with respect to all wavelength bands of the visible light is lower than or equal to 6%.

4. The imaging device according to claim 2, wherein the color filter of the at least one second pixel is a black color filter having absorption in all wavelength bands of the visible light.

5. The imaging device according to claim 2, wherein the color filter of the at least one second pixel is a blue color filter that transmits blue light or a green color filter that transmits green light.

6. The imaging device according to claim 1, further comprising a plurality of pixel groups each including the at least one first pixel and the at least one second pixel,
wherein the plurality of pixel groups are two-dimensionally arranged in the plan view.

7. The imaging device according to claim 6, wherein
each of the plurality of pixel groups further includes a third pixel and a fourth pixel,
the photoelectric conversion layer lies astride the at least one first pixel, the at least one second pixel, the third pixel, and the fourth pixel and is shared by the at least one first pixel, the at least one second pixel, the third pixel, and the fourth pixel,
the third pixel includes a second pixel electrode that collects third signal charge generated by the photoelectric conversion layer and that has a light blocking effect on the visible light and the near-infrared light,
the fourth pixel includes a third pixel electrode that collects fourth signal charge generated by the photoelectric conversion layer and that has a light blocking effect on the visible light and the near-infrared light,
the at least one first pixel, the third pixel, and the fourth pixel are each located above a surface of the photoelectric conversion layer on which light is incident and each include a color filter that blocks a component of a wavelength band of part of the visible light, and
the color filter of the at least one first pixel, the color filter of the third pixel, and the color filter of the fourth pixel block light of wavelength bands of the visible light, the wavelength bands being different from one another.

8. The imaging device according to claim 1, further comprising a pixel array including a plurality of pixels, wherein
the at least one first pixel includes a plurality of first pixels,
the at least one second pixel includes a plurality of second pixels,
the plurality of pixels include the plurality of first pixels and the plurality of second pixels, and
a proportion of the plurality of second pixels in all pixels included in the pixel array is smaller than 25%.

9. The imaging device according to claim 1, wherein
the photoelectric conversion layer has sensitivity in a band of wavelengths of 400 nm to 600 nm, and
the sensitivity of the photoelectric conversion layer gradually decreases with increasing wavelength longer than 600 nm.

10. The imaging device according to claim 1, further comprising a metal grid or an air gap located between the first pixel electrode and the photodiode in the plan view and above a surface of the photoelectric conversion layer on which light is incident.

11. The imaging device according to claim 1, further comprising:
a substrate that includes the photodiode; and
a metal layer located between the photoelectric conversion layer and the substrate in a stack direction and between the first pixel electrode and the photodiode in the plan view,
wherein the photoelectric conversion layer is stacked over the substrate.

12. The imaging device according to claim 1, further comprising a shield electrode that is located between the first pixel electrode and the photodiode in the plan view and that has a light blocking effect on the visible light and the near-infrared light.

13. The imaging device according to claim 12, further comprising:
a substrate that includes the photodiode; and
a via that is connected to the shield electrode, that is located between the shield electrode and the substrate and between the first pixel electrode and the photodiode in the plan view, and that has a light blocking effect on the visible light and the near-infrared light,
wherein the photoelectric conversion layer is stacked over the substrate.

14. The imaging device according to claim 1, wherein
the at least one first pixel further includes a first microlens,
the at least one second pixel further includes a second microlens, and
a curvature of the second microlens is smaller than a curvature of the first microlens.

15. The imaging device according to claim 1, wherein
the at least one first pixel further includes a first microlens,
the at least one second pixel further includes a second microlens, and
the first pixel electrode is eccentrically located in one predetermined direction from a center of the first microlens in the plan view.

16. A camera system comprising:
the imaging device according to claim 1; and
a double band-pass filter that has transmitting regions in both a wavelength band of the visible light and a wavelength band of the near-infrared light,
wherein the visible light and the near-infrared light transmitted through the double band-pass filter are incident on the photoelectric conversion layer.

17. A camera system comprising:
the imaging device according to claim 1; and
a light source that emits the near-infrared light,
wherein the imaging device detects reflected light produced by an object reflecting the near-infrared light emitted by the light source.
